(19) United States
(12) Patent Application Publication
(10) Pub. No.: US 2026/0360405 A1
(43) Pub. Date: Nov. 12, 2026

(54) OPERATION METHOD OF CLOCK-SYNCHRONOUS SEMICONDUCTOR MEMORY DEVICE

(71) Applicant: Unisantis Electronics Singapore Pte. Ltd., Singapore (SG)

(72) Inventors: Yoshihisa IWATA, Tokyo (JP); Koji SAKUI, Tokyo (JP); Nozomu HARADA, Tokyo (JP)

(21) Appl. No.: 19/205,557

(22) Filed: May 12, 2025

(51) Int. Cl. G11C 11/4076; G11C 11/4096; G11C 11/4097

(52) U.S. Cl. CPC G11C 11/4076; G11C 11/4096; G11C 11/4097

(57) ABSTRACT

Proposed is an optimal operation method for a memory cell that stores data based on the amount of electricity accumulated in a floating body and that satisfies the operational specifications of an existing SDRAM. A clock-synchronous dynamic semiconductor memory device using a memory cell that stores two logical values based on the amount of electricity accumulated in a floating body writes the two logical values into the memory cell not at the same time but in response to different commands or at different timings. One of the two logical values is written into the memory cell in response to a command for transitioning the memory cell from a selected state to a deselected state or at a timing for transitioning the memory cell from the selected state to the deselected state.

### BACKGROUND OF THE INVENTION

### 1. Field of the Invention

The present invention relates to operation methods of clock-synchronous dynamic semiconductor memory devices (referred to as "SDRAM" hereinafter) that are compliant with the standard specifications of double-data-rate (referred to as "DDR" hereinafter) clock-synchronous dynamic semiconductor memory devices, low-power-double-data-rate (referred to as "LPDDR" hereinafter) clock-synchronous dynamic semiconductor memory devices, and graphics-double-data-rate (referred to as "GDDR" hereinafter) clock-synchronous dynamic semiconductor memory devices and that use memory cells that distinguish stored data based on the amount of electricity accumulated in floating bodies.

### 2. Description of the Related Art

Dynamic semiconductor memory devices (referred to as "DRAM" hereinafter) are widely used as semiconductor memory devices and are being further increased in density and capacity. Therefore, an area occupied by each memory cell of the DRAM on the silicon substrate surface is decreasing.

Each memory cell of an existing DRAM is constituted of one metal-oxide-semiconductor (MOS) field-effect transistor (referred to as "transistor" hereinafter) and one capacitor. Even if the area occupied by each memory cell on the silicon substrate surface is decreased for increased density and increased capacity, the capacity of the capacitor needs to be kept fixed or the rate of decrease in the capacitor's capacity needs to be lower than the rate of decrease in the memory cell's occupying area in order for the memory cell to fulfill its function.

Therefore, each memory cell of an existing DRAM has a three-dimensional structure. Specifically, the memory cell has a structure with a tubular capacitor extending upward perpendicularly to a transistor constituting the memory cell on the silicon substrate surface.

For a further increase in density and capacity, the capacitor is being increased in aspect ratio. Specifically, the length of the tube of the tubular capacitor is increased relative to the diameter thereof, and the tube diameter is decreased. An increase in length of the tube makes the manufacturing process more difficult.

The tube diameter of the capacitor is determined based on the thickness of two capacitor electrodes and the thickness of an insulating film between the two electrodes. Since the insulation properties of the insulating film are necessary for the capacitor to fulfill its function, there are physical limits to reducing the tube diameter of the capacitor.

In other words, there are limits to achieving a higher aspect ratio of the capacitor, meaning that there are also limits to achieving increased density and increased capacity in a DRAM in which each memory cell is constituted of one transistor and one capacitor.

Thus, US 2020/0227416 A1 (referred to as "Patent Literature 1" hereinafter) and US 2020/0043941 A1 (referred to as "Patent Literature 2" hereinafter) propose increasing the capacity by stacking memory cell arrays each including memory cells, each made of one transistor and one capacitor, arranged in a matrix in two orthogonal directions so as to be parallel to a semiconductor substrate.

However, in contrast to the stacked memory cell arrays, a circuit for driving the memory cells is not stacked and exists only on a silicon wafer surface. Naturally, a connection section between the circuit for driving the memory cells and the stacked memory cell arrays is necessary.

In other words, when the number of layers of memory cell arrays is increased while the performance, such as the speed and the refresh interval, and the power consumption are maintained in an existing DRAM, an explosive increase in the area of the aforementioned connection section is unavoidable. Moreover, an increase in the number of layers for achieving increased capacity also leads to an increase in manufacturing steps.

Therefore, with regard to the stacking of memory cell arrays each including memory cells, each made of one transistor and one capacitor, arranged in a matrix in two orthogonal directions so as to be parallel to a semiconductor substrate, there is a high possibility that this is not an optimal measure for achieving increased density and increased capacity in a DRAM.

A proposed alternative to a memory cell constituted of one transistor and one capacitor is a memory cell constituted of one transistor and not having a capacitor serving as a major factor for making the manufacturing process complicated. For example, see US 5448513 (referred to as "Patent Literature 3" hereinafter), US 7280399 B2 (referred to as "Patent Literature 4" hereinafter), Hsing-jen Wann and Chenming Hu, "A Capacitorless DRAM Cell on SOI Substrate", IEEE International Electron Device Meeting Technical Digest, pp.635-638 (1993) (referred to as "Non-Patent Literature 1" hereinafter), P. C. Fazan, S. Okhonin, M. Nagoga and J. M. Sallese, "A Simple 1-Transistor Capacitor-Less Memory Cell for High Performance Embedded DRAMs," Proceedings of the IEEE 2002 Custom Integrated Circuits Conference, pp.99-102 (2002) (referred to as "Non-Patent Literature 2" hereinafter), C. Kuo, T. J. King, and C. Hu: "A Capacitorless Double-Gate DRAM Cell", IEEE Electron Device Letter, Vol. 23, No.6, pp.345-347 (2002) (referred to as "Non-Patent Literature 3" hereinafter), T. Ohsawa, K. Fujita, T. Higashi, Y. Iwata, T. Kajiyama, Y. Asao, and K. Sunouchi, "Memory design using a one-transistor gain cell on SOI", IEEE Journal of Solid State Circuits, vol.37, No.11, pp1510-1522 (2002) (referred to as "Non-Patent Literature 4" hereinafter), and E. Yoshida and T. Tanaka, "A Capacitorless 1T-DRAM Technology Using Gate-Induced Drain-Leakage (GIDL) Current for Low-Power and High-Speed Embedded Memory", IEEE Transaction on Electron Devices, vol.53, No.4, pp692-697 (2006) (referred to as "Non-Patent Literature 5" hereinafter).

A general operation principle of a memory cell constituted of one transistor is as follows.

The body of each memory cell constituted of one transistor is separated from other memory cells to serve as a floating body used as a storage region. An example of a floating body is a region indicated by reference sign 203 in FIG. 9C. Electric charge is accumulated in the floating body in place of a capacitor of a memory cell constituted of one transistor and one capacitor.

Various writing methods have been proposed (see Patent Literature 3, Patent Literature 4, and Non-Patent Literatures 1 to 5), but are all in common that the amount of electricity in the floating body is differentiated between the "0" state and the "1" state in accordance with a write operation. When the amount of electricity is different, the electric potential of the floating body changes. When the electric potential of the floating body changes, the threshold voltage changes due to the back gate bias effect. Specifically, the "0" state and the "1" state with different threshold voltage values can be created in accordance with a write operation.

Because the threshold voltage value is different between the "0" state and the "1" state, the electric current flowing from the drain to the source differs between the "0" state and the "1" state even if the same voltage is applied with respect to the gate voltage, the drain voltage, and the source voltage. Therefore, "1" and "0" can be distinguished from each other in accordance with the magnitude or the presence or absence of electric current flowing to the drain.

The following description relates to problems occurring when a memory cell constituted of one transistor is used in an SDRAM as an alternative to a memory cell constituted of one transistor and one capacitor based on specific operating voltage conditions indicated in known literatures about a memory cell constituted of one transistor.

TABLE III in Non-Patent Literature 5 shows the operating voltage conditions. In addition to the drain voltage, the gate voltage is also different between a "0" write operation and a "1" write operation.

FIG. 9 in Non-Patent Literature 5 illustrates the state of each operation when a memory cell array has a 2-row-by-2-column configuration. This indicates that, for a "0"-write-targeted memory cell and a "1"-write-targeted memory cell that are within one memory cell array, the write operations cannot be performed at the same timing.

TABLE 1 in Non-Patent Literature 2 shows the operating voltage conditions. Similar to the operating conditions shown in TABLE III in Non-Patent Literature 5, the gate voltage is different between a "0" write operation and a "1" write operation. However, the drain voltage is the same between a "0" write operation and a "1" write operation.

FIG. 7 in Non-Patent Literature 2 illustrates the state of each operation when a memory cell array has a 2-row-by-2-column configuration. A "0" write operation and a "1" write operation can be performed at the same time on two memory cells that share a drain.

However, when read operations are to be performed at the same time from memory cells sharing a drain as in the write operations, the read operations cannot be performed at the same time since the drain is shared.

"1" and "0" are distinguished from each other by applying a fixed voltage to each of the gate and the drain and determining the magnitude or the presence or absence of electric current flowing to the drain. Therefore, when the drain is shared, it is not possible to determine which memory cell the electric current is flowing to.

In other words, when reading is possible from multiple memory cells within one memory cell array, the write operations cannot be performed at the same timing on a "0"-write-targeted memory cell and a "1"-write-targeted memory cell that are within the one memory cell array.

In the memory cell indicated in Non-Patent Literature 1 and Patent Literature 3, the voltage of the word line is the same between a "1" write operation and a "0" write operation.

However, the "0" write operation actually being performed is a purging operation. Therefore, in the memory cell indicated in Non-Patent Literature 1 and Patent Literature 3, a "0" write operation and a "1" write operation cannot be actually performed at the same timing.

In the operating conditions indicated in Non-Patent Literature 4, a "0" write operation and a "1" write operation can be performed at the same timing on multiple memory cells within one memory cell array, and read operations can be performed at the same timing on the multiple memory cells having undergone the write operations.

However, there is a large difference between the electric potential of the bit line connected to the drain of each memory cell when a "0" write operation is performed and the electric potential of the bit line connected to the drain of each memory cell when a "1" write operation is performed. Therefore, the distance between the memory cells cannot be reduced, and the area cannot be reduced relative to a memory cell constituted of one transistor and one capacitor in an existing DRAM.

In order to reduce the distance between the memory cells to allow the memory cells to serve as an alternative to those of an existing DRAM, the "0" write operation and the "1" write operation need to be performed at different timings.

When the memory-cell operating conditions indicated in Non-Patent Literature 2, Non-Patent Literature 5, Non-Patent Literature 1, and Patent Literature 3 are simply used, the "0" write operation and the "1" write operation need to be performed at different timings.

Because the "0" write operation and the "1" write operation are performed by utilizing different physical characteristics to change the amount of electricity in the floating body, the optimal operating conditions for performing the "0" write operation and the "1" write operation are naturally different to begin with.

On the other hand, a "0" write operation and a "1" write operation can be performed at the same timing on a memory cell used in an existing DRAM and constituted of one transistor and one capacitor.

A memory cell used in an existing DRAM and constituted of one transistor and one capacitor uses the one transistor as a switch, and charges or discharges the one capacitor, thereby enabling a "0" write operation and a "1" write operation. Therefore, the "0" write operation and the "1" write operation do not need to be performed separately whatsoever.

An existing DRAM is of a clock synchronous type for increasing the data input-output speed, has operational specifications for performing input and output of data by using both edges of a clock pulse, and has standard specifications created for a double-data-rate (referred to as "DDR" hereinafter) SDRAM. For the standard specifications of DDR-SDRAM, see DOUBLE DATA RATE (DDR) SDRAM, JESD79F (referred to as "Non-Patent Literature 9" hereinafter), DDR2 SDRAM STANDARD, JESD79-2F (referred to as "Non-Patent Literature 10" hereinafter), DDR3 SDRAM STANDARD, JESD79-3F (referred to as "Non-Patent Literature 11" hereinafter), DDR4 SDRAM STANDARD, JESD79-4B (referred to as "Non-Patent Literature 12" hereinafter), and DDR5 SDRAM; JESD79-5C (referred to as "Non-Patent Literature 13" hereinafter).

Furthermore, the standard specifications of LPDDR oriented toward low power consumption and the standard specifications of GDDR oriented toward graphics are also created based on their applications. For the standard specifications of LPDDR, see LOW POWER DOUBLE DATA RATE (LPDDR) SDRAM STANDARD, JESD209B (referred to as "Non-Patent Literature 14" hereinafter), LOW POWER DOUBLE DATA RATE 2 (LPDDR2), JESD209-2F (referred to as "Non-Patent Literature 15" hereinafter). For the standard specifications of GDDR, see GRAPHICS DOUBLE DATA RATE (GDDR4) SGRAM STANDARD, SDRAM3.11.5.8.R16.01 (referred to as "Non-Patent Literature 19" hereinafter), GRAPHICS DOUBLE DATA RATE (GDDR5) SGRAM STANDARD, JESD212C.01 (referred to as "Non-Patent Literature 20" hereinafter), GRAPHICS DOUBLE DATA RATE (GDDR5X) SGRAM STANDARD; JESD232A.01 (referred to as "Non-Patent Literature 21" hereinafter), GRAPHICS DOUBLE DATA RATE 6 (GDDR6) SGRAM STANDARD, JESD250D (referred to as "Non-Patent Literature 22" hereinafter), and GRAPHICS DOUBLE DATA RATE 7 SGRAM STANDARD (GDDR7), JESD239A (referred to as "Non-Patent Literature 23" hereinafter).

The standard specifications indicated in Non-Patent Literature 9 to Non-Patent Literature 23 are created such that there are no issues in the operation of an SDRAM using a memory cell made of one transistor and one capacitor. However, the standard specifications are not necessarily created such that there are no issues in the operation of a capacitor-less memory cell that is constituted of one transistor and that requires that a "0" write operation and a "1" write operation be performed at different timings.

Therefore, in order to use a capacitor-less memory cell constituted of one transistor as an alternative to a memory cell constituted of one transistor and one capacitor, it is necessary to use a memory cell that requires that a "0" write operation and a "1" write operation be performed at different timings and to comply with the standard specifications indicated in Non-Patent Literature 9 to Non-Patent Literature 23 and created based on the assumption of using a memory cell that enables a "0" write operation and a "1" write operation at the same timing.

In other words, as mentioned above, while a memory cell that does not have a capacitor as a structural object and that accumulates electric charge in a floating body and distinguishes stored data based on the amount of electricity in the floating body has been proposed as an alternative to a memory cell that is used in an existing SDRAM and that is constituted of one transistor and one capacitor, there is a problem in that an operation method that complies with the standard specifications of DDR-SDRAM (e.g., the standard specifications of DDR-SDRAM indicated in Non-Patent Literature 9 to Non-Patent Literature 23) has not been indicated.

The above point of discussion relates to a read operation and a write operation with respect to a memory cell and can thus be directly applied to the standard specifications of DDR-SDRAM to be created in the future.

### SUMMARY OF THE INVENTION

An object of the present invention is to provide an operation method suitable for a memory cell that distinguishes stored data based on the amount of electricity accumulated in a floating body while being compliant with the standard specifications of DDR-SDRAM (e.g., the standard specifications of DDR-SDRAM indicated in Non-Patent Literature 9 to Non-Patent Literature 23).

In order to solve the aforementioned problems, the characteristics of commands and operations according to the standard specifications of DDR-SDRAM (e.g., the standard specifications of DDR-SDRAM indicated in Non-Patent Literature 9 to Non-Patent Literature 23) are utilized.

Specifically, in order to perform a read operation and a write operation on an SDRAM compliant with the standard specifications of DDR-SDRAM (e.g., the standard specifications of DDR-SDRAM indicated in Non-Patent Literature 9 to Non-Patent Literature 23), the fact that a memory cell needs to be set to a selected state is utilized.

Moreover, in order to solve the aforementioned problems, a data register included in an existing SDRAM and located between an input-output terminal and the memory cell is used.

Specifically, when a write operation is to be performed on the SDRAM from an external device of the SDRAM, data received from the input-output terminal is written into the data register located between the input-output terminal and the memory cell instead of being written into the memory cell, and can be written into the memory cell at another timing. However, the write operation needs to be performed before the memory cell is transitioned from the selected state to the deselected state.

In detail, a "0" write operation and a "1" write operation are performed at different timings in the following manner.

The SDRAM according to the present invention receives a command for selecting memory cells according to the standard specifications of DDR-SDRAM (e.g., the standard specifications of DDR-SDRAM indicated in Non-Patent Literature 9 to Non-Patent Literature 23) and temporarily copies data of the memory cells selected in response to the received command to data registers.

Subsequently, the SDRAM according to the present invention writes data of a first logical value (e.g., "0") of binary data into all of the selected memory cells.

The SDRAM according to the present invention performs a write operation, at a data input timing from the input-output terminal, on the data registers in response to a write command or a write command with auto-pre-charge according to the standard specifications of DDR-SDRAM (e.g., the standard specifications of DDR-SDRAM indicated in Non-Patent Literature 9 to Non-Patent Literature 23), but does not perform a write operation on the memory cells in the selected state.

Before the selected memory cells compliant with the standard specifications of DDR-SDRAM (e.g., the standard specifications of DDR-SDRAM indicated in Non-Patent Literature 9 to Non-Patent Literature 23) are transitioned from the selected state to the deselected state, the SDRAM according to the present invention writes data (e.g., "1") of the second logical value of the binary data into the selected memory cells in accordance with the data in the data registers.

Due to being prior to the transitioning of the selected memory cells from the selected state to the deselected state, data that is input to the SDRAM prior this time point and that needs to be written into the memory cells in the selected state is written in all of the data registers. By performing the write operation on the selected memory cells in accordance with the data in the data registers, there is no write omission to the selected memory cells.

Furthermore, since data in an already-erased memory cell remains as a copy in a data register, the data in the selected memory cells can be recovered by performing a write operation on the selected memory cells in accordance with the data in the data registers.

### BRIEF DESCRIPTION OF THE DRAWINGS

FIG. 1 is a block diagram of an SDRAM and is a selective extraction of parts related to input and output of data and read-write operations with respect to memory cells;

FIG. 2 is a state transition diagram related to a first embodiment and illustrates the states of the memory cells and data registers within the SDRAM in addition to the state of the SDRAM;

FIG. 3 is a state transition diagram related to a second embodiment and corresponding to a state transition diagram in FIG. 10, and illustrates the state transitions of the memory cells and the data registers within the SDRAM in addition to the state transition of the SDRAM;

FIG. 4 is a state transition diagram related to a third embodiment and corresponding to the state transition diagram in FIG. 10, and illustrates the state transitions of the memory cells and the data registers within the SDRAM in addition to the state transition of the SDRAM;

FIG. 5 is a state transition diagram related to a fourth embodiment and corresponding to the state transition diagram in FIG. 10, and illustrates the state transitions of the memory cells and the data registers within the SDRAM in addition to the state transition of the SDRAM;

FIG. 6 is a state transition diagram related to a fifth embodiment and corresponding to the state transition diagram in FIG. 10, and illustrates the state transitions of the memory cells and the data registers within the SDRAM in addition to the state transition of the SDRAM;

FIG. 7 is a state transition diagram related to a sixth embodiment and corresponding to the state transition diagram in FIG. 10, and illustrates the state transitions of the memory cells and the data registers within the SDRAM in addition to the state transition of the SDRAM;

FIG. 8 is a block diagram of a memory cell array of an SDRAM according to a seventh embodiment;

FIG. 9A is a circuit diagram of a capacitor-less memory cell that is usable in the SDRAM according to the present invention and that is constituted of a single MOS field-effect transistor;

FIG. 9B is a block diagram representation of FIG. 9A;

FIG. 9C is a cross-sectional representation of FIG. 9A; and

FIG. 10 is a state transition diagram obtained by selectively extracting parts related to the present invention from a state transition diagram of an existing SDRAM.

### DESCRIPTION OF THE PREFERRED EMBODIMENTS

An operation method of an SDRAM according to the present invention will be described below with reference to the drawings.

### First Embodiment

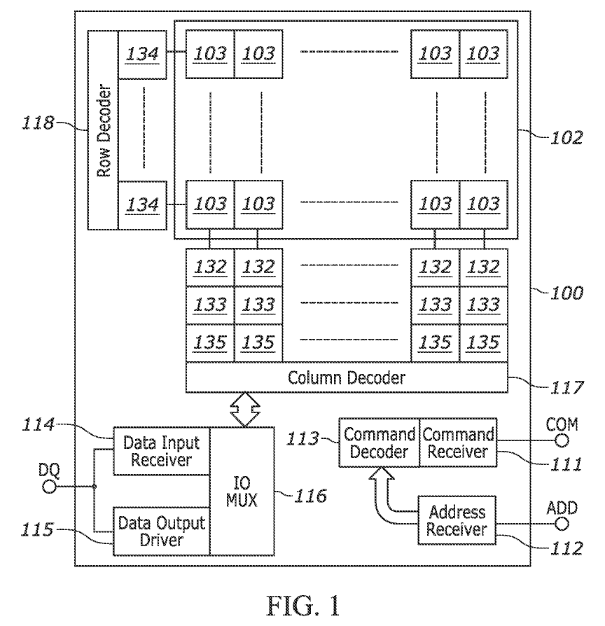

An operation method of an SDRAM (as an example of a "clock-synchronous semiconductor memory device" according to the claims) according to a first embodiment of the present invention will now be described with reference to FIGS. 1, 2, and 10.

FIG. 1 is a block diagram of the SDRAM for explaining each embodiment of the present invention. The block diagram is a selective extraction of parts related to input-output operations with respect to the SDRAM and read-write operations with respect to memory cells ("memory cells" according to the claims).

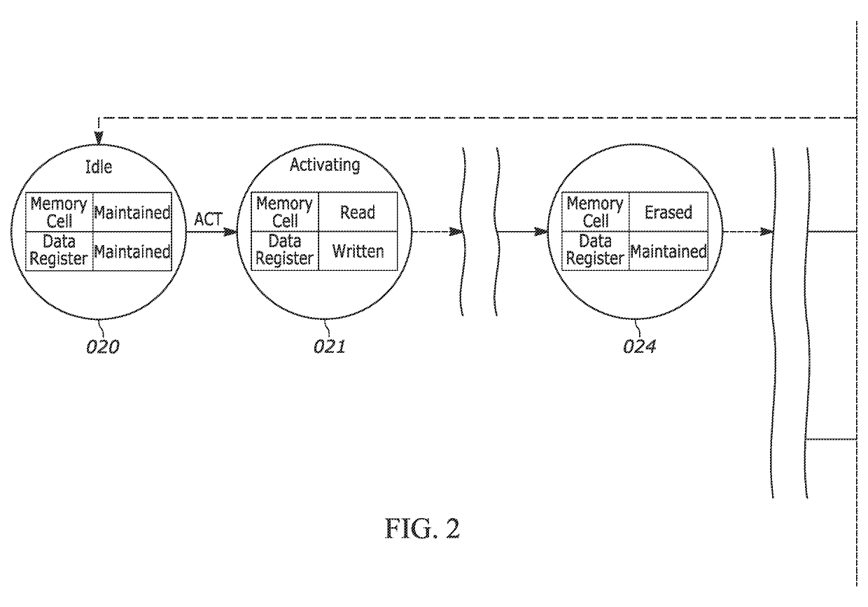

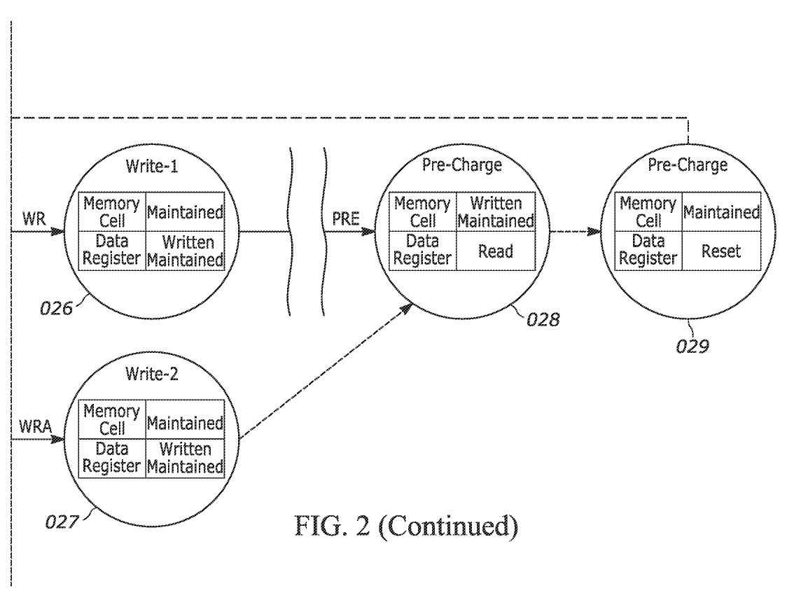

FIG. 2 is a state transition diagram illustrating, in a tabular form, the states of the memory cells and data registers ("data register" according to the claims) that operate by being selected, in addition to the state of the SDRAM as viewed from an external device, and is a selective extraction of characteristic parts of the operation method of the SDRAM according to the present invention.

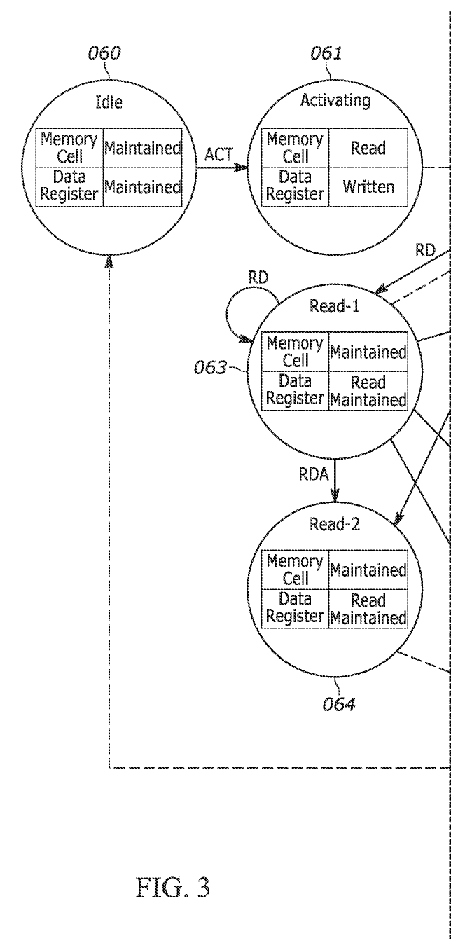

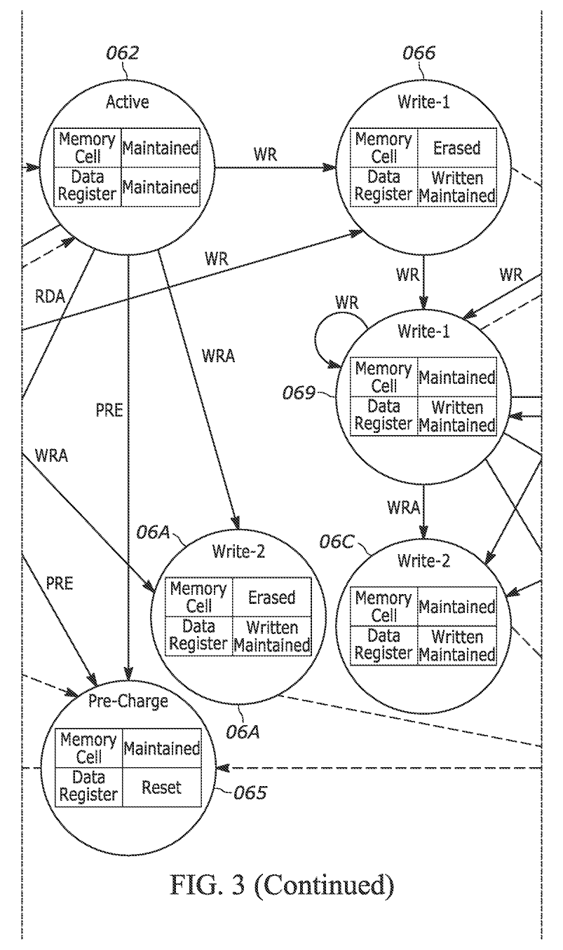

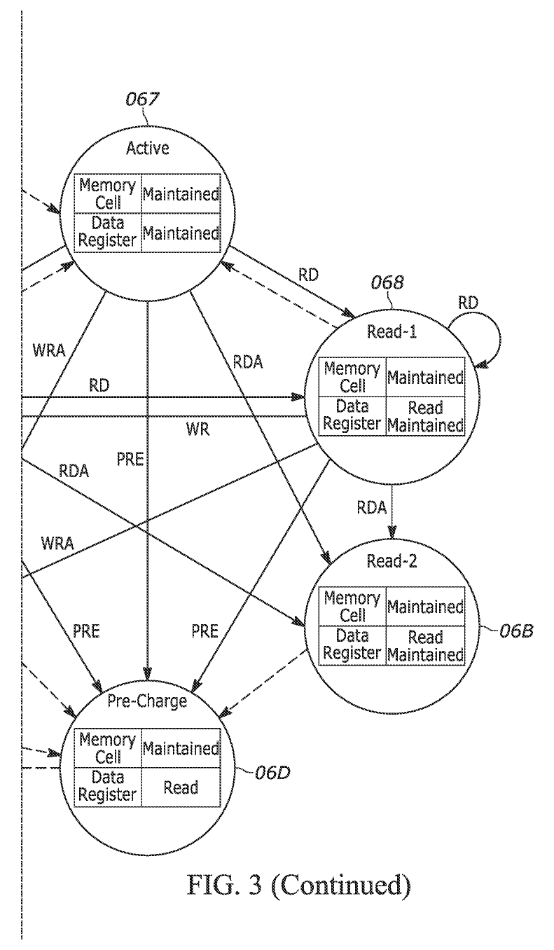

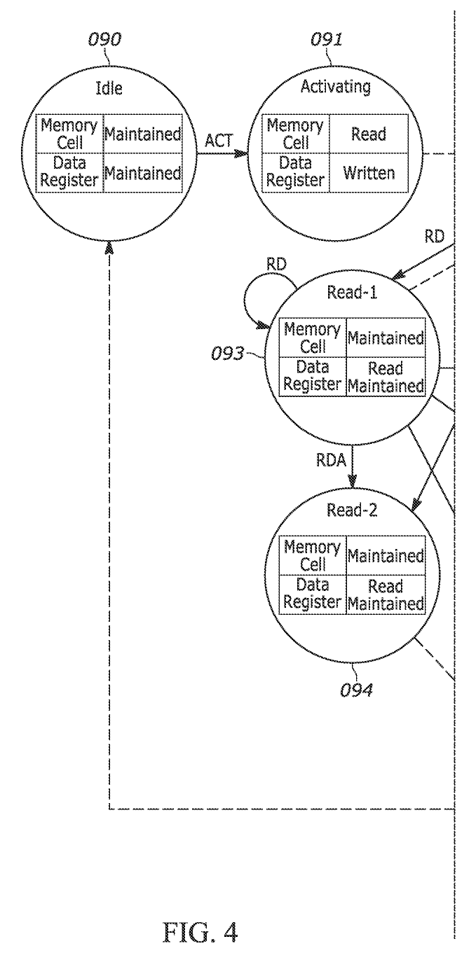

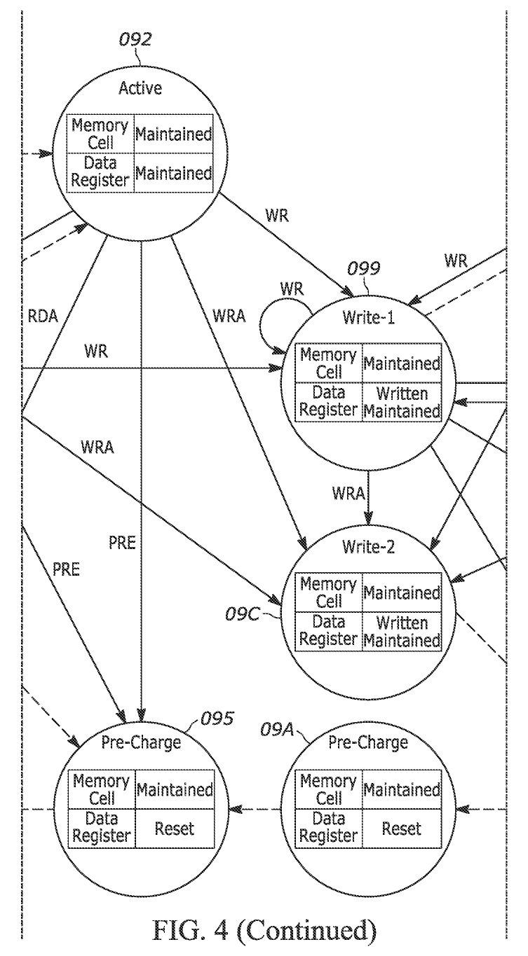

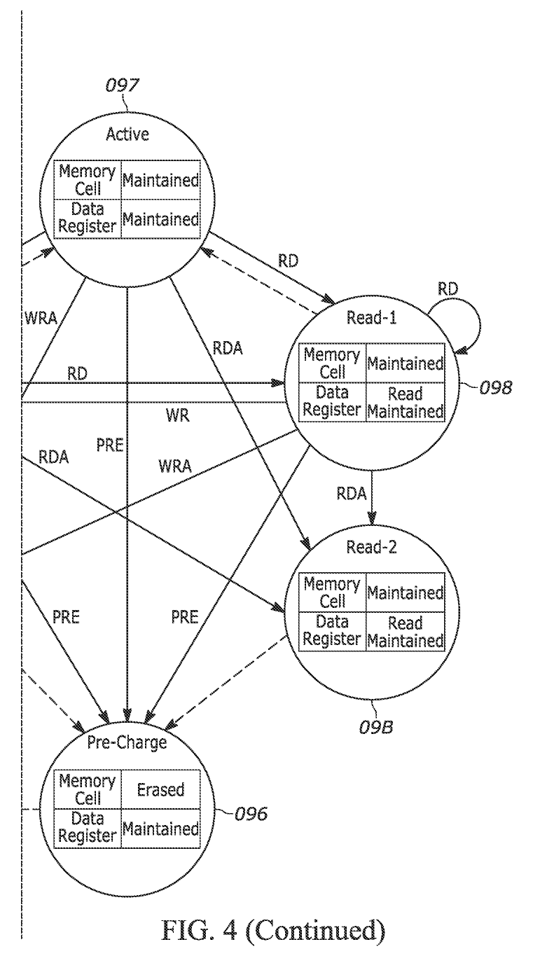

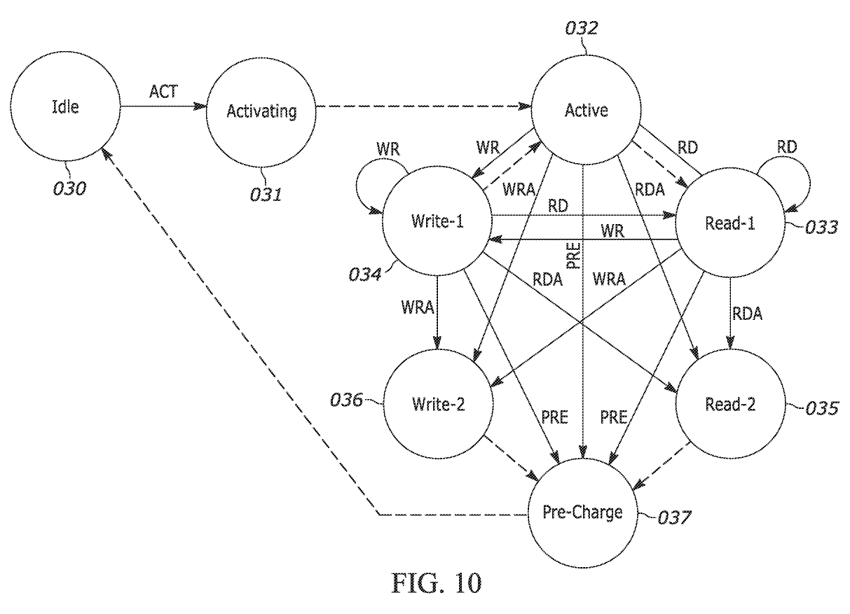

FIG. 10 is a selective extraction of state transitions related to input-output operations (write operation and read operation) with respect to an existing SDRAM from, for example, FIG. 4 in Non-Patent Literature 11, the drawing corresponding to the paragraph "3.1 Simplified state diagram" in Non-Patent Literature 12, FIG. 3 in Non-Patent Literature 15, FIG. 3 in Non-Patent Literature 22, and FIG. 11 in Non-Patent Literature 23. The SDRAM according to the present invention needs to operate in compliance with the state transition diagram.

First, the state transition diagram illustrated in FIG. 10 will be described.

The state of the SDRAM as viewed from the external device, controlling the SDRAM, of the SDRAM is indicated within each circle.

Each solid arrow indicates that the state transitions as a result of reception of a command substantially denoted by a sign accompanying the arrow, and each dashed arrow indicates that the state transitions regardless of a command.

An existing SDRAM has multiple logically divided configuration units, called banks, which are independently operable memory regions. Therefore, the data registers and the memory cells are unique to each bank and are not shared between the banks. If multiple banks are provided, a state shown in the state transition diagram in FIG. 10 may be regarded as a state of one of the banks within the SDRAM.

However, the problems to be solved by the present invention and the gist of the present invention are not dependent on the number of banks. This is because the read-write operations with respect to the memory cells and the data registers in each bank are not dependent on the operation and state of another bank.

In order to simplify the description, this description, including FIG. 1, is targeted to an SDRAM having only one bank. Therefore, each state illustrated in the state transition diagram in FIG. 10 refers to the state of the SDRAM as viewed from the external device, controlling the SDRAM, of the SDRAM.

Each of the commands denoted by signs accompanying the solid arrows in FIG. 10 will be described below.

Each of the commands illustrated in FIG. 10 is included in a command set that the existing SDRAM has and that is related to a write operation and a read operation with respect to the SDRAM. The commands are only those necessary for explaining the problems to be solved by the present invention and the gist of the present invention.

A command ACT ("active command" according to the claims) is a command issued by the external device of the SDRAM for requesting the SDRAM to have memory cells in a selected state.

A command PRE ("pre-charge command" according to the claims) is a command issued by the external device of the SDRAM for requesting the SDRAM to transition the memory cells from the selected state to the deselected state.

A command RD ("read command" according to the claims) is a command issued by the external device of the SDRAM to set an input-output terminal to an outputtable state to read data from the SDRAM.

A command RDA ("read command with auto-pre-charge" according to the claims) is a command issued by the external device of the SDRAM for setting the input-output terminal to an outputtable state to read data from the SDRAM and also for transitioning the memory cells from the selected state to the deselected state.

A command WR ("write command" according to the claims) is a command issued by the external device of the SDRAM for setting the input-output terminal to an inputtable state to write data into the SDRAM.

A command WRA is a command issued by the external device of the SDRAM for setting the input-output terminal to an inputtable state to write data into the SDRAM and also for transitioning the memory cells from the selected state to the deselected state.

Each state illustrated in FIG. 10 is the state of the SDRAM as viewed from the external device, controlling the SDRAM, of the SDRAM.

An idle state 030 is a standby state where the SDRAM does not have memory cells in the selected state.

An activating state 031 is a state where the SDRAM is operating to have memory cells in the selected state.

An active state 032 is a standby state where the SDRAM has memory cells in the selected state.

A pre-charge state 037 is a state where the SDRAM is transitioning the memory cells from the selected state to the deselected state.

A read-1 state 033 is a state where the external device of the SDRAM can read data from the SDRAM.

A read-2 state 035 is a state where the external device of the SDRAM can read data from the SDRAM. After a lapse of a predetermined time period compliant with the standard specifications of DDR-SDRAM (e.g., the standard specifications of DDR-SDRAM indicated in Non-Patent Literature 9 to Non-Patent Literature 23), the SDRAM transitions to the pre-charge state 037 even if the command PRE is not input to the SDRAM.

A write-1 state 034 is a state where the external device of the SDRAM can write data into the SDRAM.

A write-2 state 036 is a state where the external device of the SDRAM can write data into the SDRAM. After a lapse of a predetermined time period compliant with the standard specifications of DDR-SDRAM (e.g., the standard specifications of DDR-SDRAM indicated in Non-Patent Literature 9 to Non-Patent Literature 23), the SDRAM transitions to the pre-charge state 037 even if the command PRE is not input to the SDRAM.

In order to perform a read operation and a write operation on the SDRAM, the memory cells need to be set to the selected state in accordance with the command ACT.

The command PRE, the command RD, the command WR, the command RDA, or the command WRA may be input with respect to the memory cells in the selected state of the SDRAM remaining in the read-1 state 033.

The command PRE, the command RD, the command WR, the command RDA, or the command WRA may be input with respect to the memory cells in the selected state of the SDRAM remaining in the write-1 state 034.

The SDRAM remaining in the read-1 state 033 or the write-1 state 034 transitions to the active state 032 after a lapse of a predetermined time period compliant with the standard specifications of DDR-SDRAM (e.g., the standard specifications of DDR-SDRAM indicated in Non-Patent Literature 9 to Non-Patent Literature 23).

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM that has transitioned to the read-2 state 035 in accordance with the command RDA transitions to the pre-charge state 037.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM that has transitioned to the write-2 state 036 in accordance with the command WRA transitions to the pre-charge state 037.

In order to set different memory cells, within the same bank as the memory cells in the selected state, to a selected state, the memory cells in the selected state first need to be set to an unselected state. In the case where the SDRAM has multiple banks, the multiple banks can each have memory cells in the selected state.

The following description relates to FIG. 1 serving as a block diagram that is a selective extraction of parts related to input-output operations with respect to the SDRAM and read-write operations with respect to the memory cells.

A command receiver 111 receives input signals via an input terminal COM, and discriminates and outputs logical values.

An address receiver 112 receives input signals via an input terminal ADD, and discriminates and outputs logical values.

A command decoder 113 receives output signals of the command receiver 111 and command-related output signals of the address receiver 112 as input signals, and analyzes the signals as commands.

A data input receiver 114 receives data via an input-output terminal DQ, and discriminates and outputs logical values.

A memory cell array 102 has memory cells 103 arranged in a matrix in two orthogonal directions in plan view.

A row decoder 118 receives address-related output signals as input signals from the address receiver 112 and selects one direction of the memory cell array 102.

A column decoder 117 receives address-related output signals as input signals from the address receiver 112 and selects one direction of the memory cell array 102 different from the direction selected by the row decoder 118.

Bit-line (referred to as "BL" hereinafter) sense amplifiers 132 are arranged adjacent to the memory cell array 102, are equal in number to the memory cells 103 arranged in one direction of the memory cell array 102, discriminates data in the memory cells 103, and writes the data into data registers 133.

The data registers 133 are arranged adjacent to the memory cell array 102, are equal in number to the memory cells 103 arranged in one direction of the memory cell array 102, and temporarily store data.

BL drivers and source-line (referred to as "SL" hereinafter) drivers forming pairs (referred to as "BL/SL drivers" hereinafter) 135 are arranged adjacent to the memory cell array 102, are equal in number to the memory cells 103 arranged in one direction of the memory cell array 102, and writes data into the memory cells 103 based on the data maintained in the data registers 133. This configuration relates to a seventh embodiment to be described later.

Word-line (referred to as "WL" hereinafter) drivers 134 are arranged adjacent to the memory cell array 102, and are equal in number to the memory cells 103 arranged in a direction different from the direction in which the BL sense amplifiers 132, the data registers 133, and the BL/SL drivers are arranged.

Each WL driver 134 drives memory cells 103 selected by the row decoder 118.

The number of memory cells 103 driven by the WL drivers 134 is equal to the number of BL sense amplifiers 132, the number of data registers 133, and the number of BL/SL drivers 135.

An IO MUX (multiplexer) 116 transfers an output from the data input receiver 114 to each data register 133 selected by the column decoder 117 when an SDRAM 100 is in a write-1 state 1 or a write-2 state.

Furthermore, the IO MUX (multiplexer) 116 transfers an output from each data register 133 selected by the column decoder 117 to a data output driver 115 when the SDRAM 100 is in a read-1 state or a read-2 state.

The data output driver 115 receives the output from the IO MUX 116 and outputs it via the input-output terminal DQ.

The SDRAM 100 according to the gist of the present invention at least has the configuration of the circuits described above.

FIG. 2 is a state transition diagram of the SDRAM 100 according to a first embodiment of the present invention, and does not express all of the state transitions illustrated in FIG. 10.

In each circle, the state of the SDRAM 100 as viewed from the external device of the SDRAM 100 is indicated, and corresponds to the state illustrated in FIG. 10. In addition, in each circle, the states of the memory cells 103 and the data registers 133 that operate by being selected are indicated in a tabular form.

Similar to FIG. 10, each solid arrow indicates that the state transitions as a result of reception of a command accompanying the arrow, and each dashed arrow indicates that the state transitions regardless of a command.

An idle state 020 corresponds to the idle state 030 in FIG. 10, an activating state 021 corresponds to the activating state 031 in FIG. 10, a write-1 state 026 corresponds to the write-1 state 034 in FIG. 10, a write-2 state 027 corresponds to the write-2 state 036 in FIG. 10, and a pre-charge state 028 and a pre-charge state 029 each correspond to the pre-charge state 037 in FIG. 10.

A state 024 in FIG. 2 may correspond to any of the active state 032 in FIG. 10, the read-1 state 033 in FIG. 10, the read-2 state 035 in FIG. 10, the write-1 state 034 in FIG. 10, the write-2 state 036 in FIG. 10, and the pre-charge state 037 in FIG. 10, and has multiple variations. Specific examples will be described later as a second embodiment to a sixth embodiment.

Each state in FIG. 2 and each state in FIG. 10 do not have a one-to-one correspondence relationship.

This is because the SDRAM 100 using memory cells that require that a "0" write operation and a "1" write operation be performed at different timings is to operate in compliance with the standard specifications indicated in Non-Patent Literature 9 to Non-Patent Literature 23 and created based on the assumption of using memory cells that enable a "0" write operation and a "1" write operation at the same timing.

Therefore, the state of the SDRAM 100 as viewed from the external device of the SDRAM 100 cannot be set identical to the state of the memory cells 103 and the state of the data registers 133, and does not need to be identical thereto.

The operation of the SDRAM 100 according to the first embodiment of the present invention will now be described with reference to the state transition diagram illustrated in FIG. 2.

The operation starts from the idle state 020 as a standby state where there are no memory cells 103 in the selected state.

In a state where the memory cells 103 are maintaining previously-written data, the data registers 133 are maintaining a reset state in accordance with an operation executed prior to the idle state 020.

Even in a case where the idle state 020 is obtained after the power is turned on, if a memory cell uses the amount of electricity accumulated in a floating body as data, it may be regarded that a state where the electric charge of the floating body is discharged is maintained. On the other hand, the data registers 133 are maintaining the reset state in accordance with a power-on sequence compliant with the standard specifications of DDR-SDRAM (e.g., the standard specifications of DDR-SDRAM indicated in Non-Patent Literature 9 to Non-Patent Literature 23).

Therefore, in the idle state 020, the memory cell field indicates a maintained state, and the data register field indicates a maintained state.

The SDRAM 100 according to the first embodiment of the present invention remaining in the idle state 020 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command ACT is received, the SDRAM 100 according to the present invention transitions from the idle state 020 to the activating state 021.

Since there is only one bank, address-related output signals of the address receiver 112 are transferred to the row decoder 118. One WL driver 134 is selected from the multiple WL drivers 134 and drives memory cells 103. The driven memory cells 103 are selected memory cells 103.

If there are multiple banks, the address-related signals received by the address receiver 112 include address signals for selecting one bank.

Data is read from the selected memory cells 103, is discriminated to "0" or "1" by the corresponding BL sense amplifiers 132, and is written into the corresponding data registers 133.

Therefore, in the activating state 021, the memory cell field indicates a read state, and the data register field indicates a written state.

In the SDRAM 100 according to the first embodiment of the present invention, after the data in the selected memory cells 103 is written into the data registers 133, data of a first logical value of the binary data can be written into the selected memory cells 103.

The timing for writing the data of the first logical value of the binary data into the selected memory cells 103 includes at least any of patterns according to the second embodiment to the sixth embodiment to be described later. Therefore, the state 024 in FIG. 2 does not clearly indicate the state of the SDRAM 100 as viewed from the external device of the SDRAM 100.

For the sake of convenience, a "0" data write operation to be executed is indicated as "erase" hereinafter. However, there is no problem in the case of writing of "1" as logical data.

An erase operation is executed by each WL driver 134 driving the WL and each BL/SL driver 135 driving the BL and SL to electric potentials suitable for the erase operation.

Therefore, in the aforementioned state 024, the memory cell field indicates an erased state, and the data register field indicates a maintained state.

The SDRAM 100 according to the first embodiment of the present invention causes the command receiver 111 to receive input signals via the input terminal COM, and causes the address receiver 112 to receive input signals via the input terminal ADD.

Output signals of the command receiver 111 and command-related output signals of the address receiver 112 become input signals of the command decoder 113. When the command decoder 113 analyzes that the command WR or the command WRA is received, the SDRAM 100 according to the present invention transitions to the write-1 state 026 or the write-2 state 027.

Since there is only one bank, address-related output signals of the address receiver 112 are transferred to the column decoder 117.

If there are multiple banks, the address-related signals received by the address receiver 112 include address signals for selecting one bank.

Data obtained as a result of the data input receiver 114 discriminating signals input via the input-output terminal DQ to "0" or "1" is written via the IO MUX 116 into data registers 133 selected by the column decoder 117 from among multiple data registers 133.

In the SDRAM 100 according to the first embodiment of the present invention, even when the command WR or the command WRA is received, a write operation is not performed on the selected memory cells 103 connected to the selected data registers 133 via the BLs connected thereto.

A write operation is not performed on unselected data registers 133. This is because the retained data is maintained as-is.

Therefore, in the write-1 state 026 or the write-2 state 027, the memory cell field indicates a maintained state, and the data register field indicates a written state and a maintained state.

If the command WRA is received, the SDRAM 100 according to the first embodiment of the present invention transitions to the pre-charge state 028 after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received from the external device of the SDRAM 100 according to the first embodiment of the present invention.

If there are multiple banks, address signals of one bank to be set to an unselected state is included in the address-related signals received by the address receiver 112 when the command WRA is received.

A time point after the lapse of the predetermined time period from the input of the command WRA corresponds to a time from when the command WR is input to when the command PRE becomes inputtable if the external device of the SDRAM 100 inputs the command WR in place of the command WRA, assuming that parameter values, such as the burst length, latency, and preamble, and the clock frequency are the same.

The SDRAM 100 according to the first embodiment of the present invention causes the command receiver 111 to receive input signals via the input terminal COM, and causes the address receiver 112 to receive input signals via the input terminal ADD.

Output signals of the command receiver 111 and command-related output signals of the address receiver 112 become input signals of the command decoder 113, and the command decoder 113 analyzes that the command PRE is received.

Since there is only one bank, address signals for designating the bank are not necessary.

If there are multiple banks, the address-related signals received by the address receiver 112 include address signals of one bank to be set to an unselected state.

Although a detailed description will be provided later in the second embodiment to the sixth embodiment, if the selected memory cells 103 is erased before the command PRE is received, the SDRAM 100 according to the first embodiment of the present invention transitions to the pre-charge state 028.

In the SDRAM 100 according to the first embodiment of the present invention, a write operation is performed on the selected memory cells 103 in the pre-charge state 028 in accordance with data read from the data registers 133.

For the sake of convenience, a "1" data write operation to be executed is indicated as "write" hereinafter. However, there is no problem in the case of writing of "0" as logical data instead of "1".

A write operation is performed only on a selected memory cell 103 where the data in the corresponding data register 133 is "1".

The write operation is executed by each WL driver 134 driving the WL and each BL/SL driver 135, where the data in the corresponding data register 133 is "1", driving the BL and SL to electric potentials suitable for the write operation.

During the write operation, each BL/SL driver 135 where the data in the corresponding data register 133 is "0" does not drive the BL and SL. Therefore, a write operation is not executed on the selected memory cell 103 where the data in the corresponding data register 133 is "0". In other words, the data in the selected memory cell 103 where the data in the corresponding data register 133 is "0" is in an erased state, that is, is maintained at "0".

Therefore, in the pre-charge state 028, the memory cell field indicates a written state and a maintained state, and the data register field indicates a read state.

Upon completion of the aforementioned write operation, the SDRAM 100 according to the present invention transitions from the pre-charge state 028 to the pre-charge state 029.

Since there is only one bank, the selected memory cells 103 are transitioned from the selected state to the deselected state. Even if the selected memory cells 103 are transitioned from the selected state to the deselected state, the data in the memory cells 103 is maintained.

On the other hand, the data registers 133 are reset.

Therefore, in the pre-charge state 029, the memory cell field indicates a maintained state, and the data register field indicates a reset state.

If there are multiple banks, address signals of one bank to be set to an unselected state are included in the address-related signals received by the address receiver 112 when the command WRA or the command PRE is received.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM 100 according to the first embodiment of the present invention transitions from the pre-charge state 029 to the idle state 020.

Unlike existing SDRAMs, when receiving the command WR or the command WRA, the SDRAM 100 according to the first embodiment of the present invention does not perform a write operation, at a data input timing from the input-output terminal DQ, on a memory cell 103 selected in accordance with address signals input and received synchronously with the command WR or the command WRA.

On the other hand, data obtained as a result of the data input receiver 114 discriminating a signal input via the input-output terminal DQ to "0" or "1" is written into a data register 133 selected in accordance with the address signals input and received synchronously with the command WR.

Before the selected memory cells 103 are transitioned from the selected state to the deselected state, the SDRAM 100 according to the first embodiment of the present invention performs a write operation on the selected memory cells 103 in accordance with the data in the data registers 133.

Data that is input to the SDRAM 100 up to this point and that needs to be written into the memory cells 103 in the selected state is written in all of the data registers 133.

Therefore, there is no write omission to the selected memory cells 103.

Moreover, data in the already-erased memory cells 103 remains as a copy in the data registers 133.

Therefore, by performing a write operation on the selected memory cells 103 in accordance with the data in the data registers 133, the data in the selected memory cells 103 can be recovered.

Similar to existing SDRAMs, when receiving the command RD, the SDRAM 100 according to the first embodiment of the present invention does not perform a read operation from the memory cell 103 selected in accordance with address signals input and received synchronously with the command RD.

A read operation from the data registers 133 having the copy of the data in the memory cells 103 selected in accordance with the command ACT is performed in advance, and the read data is output to the input-output terminal DQ by the data output driver 115.

Therefore, when the command RD is received after the command WR is received, since the data is written in the data register 133 whether the address signals input and received synchronously with the command RD is the same as the address signals input and received synchronously with the command WR or whether a write operation has not been performed on the memory cell 103, there is no problem in the read data.

Accordingly, even when the memory cells used have different optimal write voltages for data "0" and data "1" and require a data "0" write operation and a data "1" write operation at different timings, it is possible to comply with the standard specifications of DDR-SDRAM (e.g., the standard specifications of DDR-SDRAM indicated in Non-Patent Literature 9 to Non-Patent Literature 23) by performing the operation in accordance with the state transition diagram in FIG. 2.

The first embodiment of the present invention offers the following features.

### Features

The SDRAM according to the first embodiment of the present invention can comply with the standard specifications of DDR-SDRAM (e.g., the standard specifications of DDR-SDRAM indicated in Non-Patent Literature 9 to Non-Patent Literature 23) while using memory cells with different optimal write voltages for data "0" and data "1" to perform a data "0" write operation and a data "1" write operation at different timings.

There are various patterns for the timings for the "0" data write operation and the "1" data write operation with respect to the memory cells in the SDRAM according to the present invention. A second embodiment, a third embodiment, a fourth embodiment, a fifth embodiment, and a sixth embodiment will now be described as specific embodiments.

### Second Embodiment

An SDRAM according to a second embodiment of the present invention first receives either the command WR or the command WRA from the external device of the SDRAM, and subsequently writes a first logical value of binary data into all of the memory cells selected in accordance with address signals input and received synchronously with the command ACT from the external device of the SDRAM.

For the sake of convenience, a "0" data write operation to be executed may sometimes be indicated as "erase" hereinafter. There is no problem in the case of a "1" write operation.

If the SDRAM according to the second embodiment of the present invention receives the command WR targeted toward the selected memory cells in a period from when the SDRAM receives the command ACT from the external device of the SDRAM to when the SDRAM receives the command PRE (the SDRAM may receive the command RD or the command WR any number of times between the command ACT and the command PRE), the SDRAM, after receiving the command PRE, writes a second logical value, different from the data written in an erase operation, of the binary data into the memory cells in accordance with the data in the data registers corresponding to the selected memory cells.

Alternatively, if the SDRAM according to the second embodiment of the present invention receives the command WR targeted toward the selected memory cells in a period from when the SDRAM receives the command ACT from the external device of the SDRAM to when the SDRAM receives the command RDA (the SDRAM may receive the command RD or the command WR any number of times between the command ACT and the command RDA), the SDRAM, after a lapse of a predetermined time period compliant with the standard specifications of DDR-SDRAM (e.g., the standard specifications of DDR-SDRAM indicated in Non-Patent Literature 9 to Non-Patent Literature 23) from when the command RDA is received, writes the second logical value, different from the data written in the erase operation, of the binary data into the selected memory cells in accordance with the data in the data registers corresponding to the selected memory cells.

A time point after the lapse of the predetermined time period from the input of the command RDA corresponds to a time from when the command RD is input to when the command PRE becomes inputtable if the command RD is input in place of the command RDA, assuming that parameter values, such as the burst length, latency, and preamble, and the clock frequency are the same.

When viewed from the external device of the SDRAM, this time point is a timing at which the memory cells may be transitioned from the selected state to the deselected state.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received from the external device of the SDRAM, the SDRAM according to the second embodiment of the present invention writes the second logical value, different from the data written in the erase operation, of the binary data into the selected memory cells in accordance with the data in the data registers corresponding to the selected memory cells.

A time point after the lapse of the predetermined time period from the input of the command WRA corresponds to a time from when the command WR is input to when the command PRE becomes inputtable if the command WR is input in place of the command WRA, assuming that parameter values, such as the burst length, latency, and preamble, and the clock frequency are the same.

When viewed from the external device of the SDRAM, this time point is a timing at which the memory cells may be transitioned from the selected state to the deselected state.

If writing of "0" as logical data is to be performed in the aforementioned erase operation, "1" data is written in accordance with the data in the corresponding data registers. If writing of "1" as logical data is to be performed in the aforementioned erase operation, "0" data is written in accordance with the data in the corresponding data registers.

When receiving the command WR or the command WRA, the SDRAM according to the second embodiment does not perform a write operation, at a data input timing from the external device of the SDRAM, on a memory cell selected in accordance with address signals input and received synchronously with the command WR or the command WRA.

However, even if the data is not written into the memory cell in response to the command WR, the data is written in the data register. After the command WR and onward, the data is read from the data register instead of the memory cell in response to the command RD, so that there is no problem in the read data.

When receiving the command ACT, if the SDRAM according to the second embodiment has not received even once the command WR targeted toward the memory cells selected in accordance with the command ACT before receiving the command RDA, the SDRAM does not perform a write operation on the selected memory cells.

When receiving the command ACT, if the SDRAM according to the second embodiment has not received even once the command WR targeted toward the memory cells selected in accordance with the command ACT before receiving the command PRE, the SDRAM does not perform a write operation on the selected memory cells.

In order to describe the operation of the SDRAM according to the second embodiment of the present invention, the block diagram of the SDRAM in FIG. 1 and a state transition diagram illustrated in FIG. 3 will be used. Since the problems to be solved by the present invention and the gist of the present invention are not dependent on the number of banks, it is assumed that there is only one bank to simplify the description.

FIG. 3 is a state transition diagram of the memory cells 103 and the data registers 133 that operate by being selected in the SDRAM 100 according to the second embodiment of the present invention, and corresponds to the state transition diagram in FIG. 10.

Similar to FIG. 2, in each circle, the state of the SDRAM 100 as viewed from the external device of the SDRAM 100 is indicated, and corresponds to the state illustrated in FIG. 10. In addition, in each circle, the states of the memory cells 103 and the data registers 133 that operate by being selected in accordance with address signals input and received synchronously with the command ACT are indicated in a tabular form.

Similar to FIG. 10, each solid arrow indicates that the state transitions as a result of reception of a command accompanying the arrow, and each dashed arrow indicates that the state transitions regardless of a command.

Differences between FIGS. 3 and 10 are due to the following reasons.

The SDRAM 100 using memory cells that require that a "0" write operation and a "1" write operation be performed at different timings is to operate in compliance with the standard specifications indicated in Non-Patent Literature 9 to Non-Patent Literature 23 and created based on the assumption of using memory cells that enable a "0" write operation and a "1" write operation at the same timing.

Therefore, the state of the SDRAM 100 as viewed from the external device of the SDRAM 100 cannot be set identical to the state of the memory cells 103 and the state of the data registers 133, and does not need to be identical thereto.

Thus, if operations with respect to the memory cells 103 and the data registers 133 are performed in a single state of the SDRAM 100, the memory cells 103 and the data registers 133 may sometimes transition between different states.

Therefore, when a transition is made from a certain state to a different state in response to the same command, even if the state of the SDRAM 100 as viewed from the external device of the SDRAM 100 is the same, the memory cells 103 and the data registers 133 may sometimes be in different states due to operations previously performed on the memory cells 103 and the data registers 133.

Similar to the state transition diagram illustrated in FIG. 2, the state transition diagram illustrated in FIG. 3 is a state transition diagram of the memory cells 103 and the data registers 133 that operate by being selected in accordance with address signals input and received synchronously with the command ACT.

Therefore, even when the SDRAM 100 according to the second embodiment of the present invention is in an activating state in response to the command ACT, a state transition does not occur in memory cells 103 and data registers 133 not selected in accordance with the address signals input and received synchronously with the command ACT.

The operation of the SDRAM 100 according to the second embodiment of the present invention will now be described with reference to the state transition diagram illustrated in FIG. 3.

The operation starts from an idle state 060 as a standby state where there are no memory cells 103 in the selected state.

In a state where the memory cells 103 are maintaining previously-written data, the data registers 133 are pre-charged in accordance with an operation executed prior to the idle state 060 or is maintaining a reset state.

Even in a case where the idle state 060 is obtained after the power is turned on, if a memory cell uses the amount of electricity accumulated in a floating body as data, it may be regarded that a state where the electric charge of the floating body is discharged is maintained.

The data registers 133 are maintaining the reset state in accordance with a power-on sequence compliant with the standard specifications of DDR-SDRAM (e.g., the standard specifications of DDR-SDRAM indicated in Non-Patent Literature 9 to Non-Patent Literature 23).

Therefore, in the idle state 060, the memory cell field indicates a maintained state, and the data register field indicates a maintained state.

The SDRAM 100 according to the second embodiment of the present invention remaining in the idle state 060 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command ACT is received, the SDRAM 100 according to the second embodiment of the present invention transitions from the idle state 060 to an activating state 061.

Address-related output signals of the address receiver 112 are transferred to the row decoder 118. One WL driver 134 is selected from the multiple WL drivers 134 and drives memory cells 103. The driven memory cells 103 are selected memory cells 103.

Data is read from the selected memory cells 103, is discriminated to "0" or "1" by the corresponding BL sense amplifiers 132, and is written into the corresponding data registers 133.

Therefore, in the activating state 061, the memory cell field indicates a read state, and the data register field indicates a written state.

When the data is read from the selected memory cells 103 and is completely stored in the data registers 133, the SDRAM 100 according to the second embodiment of the present invention transitions from the activating state 061 to an active state 062.

Alternatively, if a command is not input from a read-1 state 063, the SDRAM 100 according to the second embodiment of the present invention transitions to the active state 062 after a lapse of a predetermined time period compliant with the standard specifications of DDR-SDRAM (e.g., the standard specifications of DDR-SDRAM indicated in Non-Patent Literature 9 to Non-Patent Literature 23).

In either case, the SDRAM 100 transitions to the active state 062 upon completion of any operation.

Therefore, in the active state 062, the memory cell field indicates a maintained state, and the data register field indicates a maintained state.

The SDRAM 100 according to the second embodiment of the present invention remaining in the active state 062 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the second embodiment of the present invention transitions from the active state 062 to the read-1 state 063.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 063, the memory cell field indicates a maintained state, and the data register field indicates a read state and a maintained state.

The SDRAM 100 according to the second embodiment of the present invention remaining in the read-1 state 063 can receive the command RD again.

In this case, the SDRAM 100 according to the second embodiment of the present invention remains in the read-1 state 063.

If the SDRAM 100 according to the second embodiment of the present invention remaining in the read-1 state 063 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 062.

When remaining in the active state 062 or the read-1 state 063, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 transitions from the active state 062 or the read-1 state 063 to a read-2 state 064.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 064, the memory cell field indicates a maintained state, and the data register field indicates a read state and a maintained state.

The SDRAM 100 according to the second embodiment of the present invention remaining in the read-2 state 064 transitions to a pre-charge state 065 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 062 or the read-1 state 063, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the second embodiment of the present invention transitions from the active state 062 or the read-1 state 063 to a write-2 state 06A.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

Data registers 133 not selected by the column decoder 117 do not perform any operation and are maintaining data.

On the other hand, the selected memory cells are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

In other words, in the write-2 state 06A, the memory cell field indicates an erased state, and the data register field indicates a written state and a maintained state.

The SDRAM 100 according to the second embodiment of the present invention remaining in the write-2 state 06A transitions to a pre-charge state 06D after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 062 or the read-1 state 063, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the second embodiment of the present invention transitions from the active state 062 or the read-1 state 063 to a write-1 state 066.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

Data registers 133 not selected by the column decoder 117 do not perform any operation and are maintaining data.

On the other hand, the selected memory cells 103 are entirely erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

In other words, in the write-1 state 066, the memory cell field indicates an erased state, and the data register field indicates a written state and a maintained state.

The SDRAM 100 according to the second embodiment of the present invention remaining in the write-1 state 066 can receive the command WR again.

In this case, upon completion of the erase operation on the selected memory cells 103, the SDRAM 100 according to the second embodiment of the present invention transitions to a write-1 state 069.

After the erase operation performed on the selected memory cells 103 and the input of data to the SDRAM 100 is completed, if the SDRAM 100 according to the second embodiment of the present invention remaining in the write-1 state 066 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to an active state 067.

In addition to the above, if the SDRAM 100 according to the second embodiment of the present invention remaining in a read-1 state 068 or the write-1 state 069 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 067.

In either case, the SDRAM 100 transitions to the active state 067 upon completion of any operation.

In other words, in the active state 067, the memory cell field indicates a maintained state, and the data register field indicates a maintained state.

When remaining in the active state 067 or the write-1 state 069, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the second embodiment of the present invention transitions from the active state 067 or the write-1 state 069 to a read-1 state 068.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 068, the memory cell field indicates a maintained state, and the data register field indicates a read state and a maintained state.

The SDRAM 100 according to the second embodiment of the present invention remaining in the read-1 state 068 can receive the command RD again.

In this case, the SDRAM 100 according to the second embodiment of the present invention remains in the read-1 state 068.

If the SDRAM 100 according to the second embodiment of the present invention remaining in the read-1 state 068 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 067.

When remaining in the active state 067 or the read-1 state 068, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the second embodiment of the present invention transitions from the active state 067 or the read-1 state 068 to the write-1 state 069.

Alternatively, if the SDRAM 100 according to the second embodiment of the present invention remaining in the write-1 state 066 receives the command WR again, the SDRAM 100 transitions to the write-1 state 069 upon completion of an erase operation performed on the selected memory cells 103.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-1 state 069, the memory cell field indicates a maintained state, and the data register field indicates a written state and a maintained state.

The SDRAM 100 according to the second embodiment of the present invention remaining in the write-1 state 069 can receive the command WR again.

In this case, the SDRAM 100 according to the second embodiment of the present invention remains in the write-1 state 069.

If the SDRAM 100 according to the second embodiment of the present invention remaining in the write-1 state 069 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 067.

When remaining in the active state 067, the read-1 state 068, or the write-1 state 069, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 transitions from the active state 067, the read-1 state 068, or the write-1 state 069 to a read-2 state 06B.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 06B, the memory cell field indicates a maintained state, and the data register field indicates a read state and a maintained state.

The SDRAM 100 according to the second embodiment of the present invention remaining in the read-2 state 06B transitions to the pre-charge state 06D after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 067, the read-1 state 068, or the write-1 state 069, the SDRAM 100 according to the second embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the second embodiment of the present invention transitions from the active state 067, the read-1 state 068, or the write-1 state 069 to a write-2 state 06C.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-2 state 06C, the memory cell field indicates a maintained state, and the data register field indicates a written state and a maintained state.

The SDRAM 100 according to the second embodiment of the present invention remaining in the write-2 state 06C transitions to the pre-charge state 06D after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received.

Alternatively, when remaining in the read-2 state 06B, the SDRAM 100 according to the second embodiment of the present invention transitions to the pre-charge state 06D after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received.

As another alternative, when remaining in the active state 067, the read-1 state 068, or the write-1 state 069, the SDRAM 100 according to the second embodiment of the present invention transitions to the pre-charge state 06D after the command decoder 113 analyzes that the command PRE is received in accordance with input signals received by the command receiver 111 and input signals received by the address receiver 112.

The SDRAM 100 according to the second embodiment of the present invention reads data from the data registers 133 and performs a write operation on the selected memory cells 103 in accordance with the data.

The write operation is performed only on the selected memory cell 103 where the data in the corresponding data register 133 is "1".

The write operation is executed by each WL driver 134 driving the WL and each BL/SL driver 135, where the data in the corresponding data register 133 is "1", driving the BL and SL to electric potentials suitable for the write operation.

During the write operation, each BL/SL driver 135 where the data in the corresponding data register 133 is "0" does not drive the BL and SL. Therefore, a write operation is not executed on the selected memory cell 103 where the data in the corresponding data register 133 is "0". In other words, the data in the selected memory cell 103 where the data in the corresponding data register 133 is "0" is maintained at "0".

Therefore, in the pre-charge state 06D, the memory cell field indicates a written state and a maintained state, and the data register field indicates a read state.

Upon completion of the write operation on the selected memory cells 103, the SDRAM 100 according to the second embodiment of the present invention transitions from the pre-charge state 06D to the pre-charge state 065.

Alternatively, when remaining in the read-2 state 064, the SDRAM 100 according to the second embodiment of the present invention transitions to the pre-charge state 065 after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received.

As another alternative, when remaining in the active state 062 or the read-1 state 063, the SDRAM 100 according to the second embodiment of the present invention transitions to the pre-charge state 065 after the command decoder 113 analyzes that the command PRE is received in accordance with input signals received by the command receiver 111 and input signals received by the address receiver 112.

The selected memory cells 103 are transitioned from the selected state to the deselected state. Even if the selected memory cells 103 are transitioned from the selected state to the deselected state, the data in the memory cells 103 is maintained.

The data registers 133 are reset.

Therefore, in the pre-charge state 065, the memory cell field indicates a maintained state, and the data register field indicates a reset state.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM 100 according to the second embodiment of the present invention transitions from the pre-charge state 065 to the idle state 060.

Unlike existing SDRAMs, when receiving the command WR or the command WRA, the SDRAM 100 according to the second embodiment of the present invention does not perform a write operation, at a data input timing from the input-output terminal DQ, on a memory cell 103 selected in accordance with address signals input and received synchronously with the command WR or the command WRA.

On the other hand, data obtained as a result of the data input receiver 114 discriminating a signal input via the input-output terminal DQ to "0" or "1" is written into a data register 133 selected in accordance with the address signals input and received synchronously with the command WR.

Before the selected memory cells 103 are transitioned from the selected state to the deselected state, the SDRAM 100 according to the second embodiment of the present invention performs a write operation on the selected memory cells 103 in accordance with the data in the data registers 133.

Data that is input to the SDRAM 100 up to this point and that needs to be written into the memory cells 103 in the selected state is written in all of the data registers 133.

Therefore, there is no write omission to the selected memory cells 103.

Moreover, data in the already-erased memory cells 103 remains as a copy in the data registers 133.

Therefore, by performing a write operation on the selected memory cells 103 in accordance with the data in the data registers 133, the data in the selected memory cells 103 can be recovered.

An existing SDRAM sometimes performs a write operation multiple times on the same memory cell. In contrast, the SDRAM 100 according to the second embodiment of the present invention performs each of a "0" data write operation and a "1" data write operation only once at most.

Similar to existing SDRAMs, when receiving the command RD, the SDRAM 100 according to the second embodiment of the present invention does not perform a read operation from the memory cells 103 selected in accordance with address signals input and received synchronously with the command RD.

A read operation from the data registers 133 having the copy of the data in the memory cells 103 selected in accordance with the command ACT is performed in advance, and the read data is output from the input-output terminal DQ by the data output driver 115.

Therefore, when the address signals input and received synchronously with the command RD after the command WR is received are the same as the address signals input and received synchronously with the command WR, even if a write operation is not performed on the memory cells 103, there is no problem in the read data since the data is written in the data registers 133.

Accordingly, even when the memory cells used have different optimal write voltages for data "0" and data "1" and require a data "0" write operation and a data "1" write operation at different timings, it is possible to comply with the standard specifications of DDR-SDRAM (e.g., the standard specifications of DDR-SDRAM indicated in Non-Patent Literature 9 to Non-Patent Literature 23) by performing the operation in accordance with the state transition diagram in FIG. 3.

This embodiment offers the following features.

### Features

The SDRAM according to the second embodiment of the present invention can comply with the standard specifications of DDR-SDRAM (e.g., the standard specifications of DDR-SDRAM indicated in Non-Patent Literature 9 to Non-Patent Literature 23) while using memory cells with different optimal write voltages for data "0" and data "1" to perform a data "0" write operation and a data "1" write operation at different timings.

### Third Embodiment

Similar to the SDRAM according to the second embodiment of the present invention, an SDRAM according to a third embodiment of the present invention does not perform a "0" write operation and a "1" write operation at the same timing on memory cells.

If the SDRAM according to the third embodiment of the present invention receives even once the command WR targeted toward the memory cells selected in accordance with address signals input and received synchronously with the command ACT in a period from when the SDRAM receives the command ACT from the external device of the SDRAM to when the SDRAM receives the command PRE (the SDRAM may receive the command RD or the command WR any number of times between the command ACT and the command PRE), the SDRAM, after receiving the command PRE, writes a first logical value of binary data into all of the memory cells selected in accordance with the address signals input and received synchronously with the command ACT from the external device of the SDRAM.

Subsequently, a write operation of a second logical value of the binary data is executed in accordance with the data in the data registers corresponding to the selected memory cells.

Alternatively, if the SDRAM according to the third embodiment of the present invention receives even once the command WR targeted toward the selected memory cells in a period from when the SDRAM receives the command ACT from the external device of the SDRAM to when the SDRAM receives the command RDA (the SDRAM may receive the command RD or the command WR any number of times between the command ACT and the command RDA), the SDRAM, after receiving the command RDA, writes a first logical value of binary data into all of the memory cells selected in accordance with the command ACT from the external device of the SDRAM after a lapse of a predetermined time period compliant with the standard specifications of DDR-SDRAM (e.g., the standard specifications of DDR-SDRAM indicated in Non-Patent Literature 9 to Non-Patent Literature 23).

Subsequently, a write operation of a second logical value of the binary data is executed in accordance with the data in the data registers corresponding to the selected memory cells.

A time point after the lapse of the predetermined time period from the input of the command RDA corresponds to a time from when the command RD is input to when the command PRE becomes inputtable if the command RD is input in place of the command RDA, assuming that parameter values, such as the burst length, latency, and preamble, and the clock frequency are the same.

When viewed from the external device of the SDRAM, this time point is a timing at which the memory cells may be transitioned from the selected state to the deselected state.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received from the external device of the SDRAM, the SDRAM according to the third embodiment of the present invention writes a first logical value of binary data into all of the memory cells selected in accordance with the address signals input and received synchronously with the command ACT from the external device of the SDRAM.

Subsequently, a write operation of a second logical value of the binary data is executed in accordance with the data in the data registers corresponding to the selected memory cells.

A time point after the lapse of the predetermined time period from the input of the command WRA corresponds to a time from when the command WR is input to when the command PRE becomes inputtable if the command WR is input in place of the command WRA, assuming that parameter values, such as the burst length, latency, and preamble, and the clock frequency are the same.

When viewed from the external device of the SDRAM, this time point is a timing at which the memory cells may be transitioned from the selected state to the deselected state.

For the sake of convenience, a "0" data write operation to be executed on all of the selected memory cells may sometimes be indicated as "erase" hereinafter. There is no problem in the case of a "1" write operation.

If writing of "0" as logical data is to be performed in the aforementioned erase operation, "1" data is written in accordance with the data in the corresponding data registers subsequently to the erase operation.

If writing of "1" as logical data is to be performed in the aforementioned erase operation, "0" data is written in accordance with the data in the corresponding data registers subsequently to the erase operation.

Similar to the SDRAM according to the second embodiment of the present invention, when the SDRAM according to the third embodiment of the present invention receives the command WR or the command WRA, the SDRAM does not perform a write operation, at a data input timing from the external device of the SDRAM, on a memory cell selected in accordance with address signals input and received synchronously with the command WR or the command WRA.

However, even if the data is not written in the memory cell in response to the command WR, the data is written in the data register. After the command WR and onward, the data is read from the data register instead of the memory cell in response to the command RD, so that there is no problem in the read data.

Similar to the SDRAM according to the second embodiment of the present invention, when the SDRAM according to the third embodiment of the present invention receives the command ACT, if the SDRAM has not received even once the command WR targeted toward the memory cells selected in accordance with the command ACT before receiving the command RDA, the SDRAM does not perform a write operation on the selected memory cells.

Similar to the SDRAM according to the second embodiment of the present invention, when the SDRAM according to the third embodiment of the present invention receives the command ACT, if the SDRAM has not received even once the command WR targeted toward the memory cells selected in accordance with the command ACT before receiving the command PRE, the SDRAM does not perform a write operation on the selected memory cells.

In order to describe the operation of the SDRAM according to the third embodiment of the present invention, the block diagram of the SDRAM in FIG. 1 and a state transition diagram illustrated in FIG. 4 will be used. Since the problems to be solved by the present invention and the gist of the present invention are not dependent on the number of banks, it is assumed that there is only one bank to simplify the description.

FIG. 4 is a state transition diagram of the memory cells 103 and the data registers 133 that operate by being selected in the SDRAM 100 according to the third embodiment of the present invention, and corresponds to the state transition diagram in FIG. 10.

Similar to FIG. 2, in each circle, the state of the SDRAM 100 as viewed from the external device of the SDRAM 100 is indicated, and corresponds to the state illustrated in FIG. 10. In addition, in each circle, the states of the memory cells 103 and the data registers 133 that operate by being selected in accordance with address signals input and received synchronously with the command ACT are indicated in a tabular form.

Similar to FIG. 2, each solid arrow indicates that the state transitions as a result of reception of a command accompanying the arrow, and each dashed arrow indicates that the state transitions regardless of a command.

Differences between FIGS. 4 and 10 are due to the following reasons.

The SDRAM 100 using memory cells that require that a "0" write operation and a "1" write operation be performed at different timings is to operate in compliance with the standard specifications indicated in Non-Patent Literature 9 to Non-Patent Literature 23 and created based on the assumption of using memory cells that enable a "0" write operation and a "1" write operation at the same timing.

Therefore, the state of the SDRAM 100 as viewed from the external device of the SDRAM 100 cannot be set identical to the state of the memory cells 103 and the state of the data registers 133, and does not need to be identical thereto.

Thus, if operations with respect to the memory cells 103 and the data registers 133 are performed in a single state of the SDRAM 100, the memory cells 103 and the data registers 133 may sometimes transition between different states.

Therefore, when a transition is made from a certain state to a different state in response to the same command, even if the state of the SDRAM 100 as viewed from the external device of the SDRAM 100 is the same, the memory cells 103 and the data registers 133 may sometimes be in different states due to operations previously performed on the memory cells 103 and the data registers 133.

Similar to the state transition diagram illustrated in FIG. 2, the state transition diagram illustrated in FIG. 4 is a state transition diagram of the memory cells 103 and the data registers 133 that operate by being selected in accordance with address signals input and received synchronously with the command ACT.

Therefore, even when the SDRAM 100 according to the third embodiment of the present invention is in an activating state in response to the command ACT, a state transition does not occur in memory cells 103 and data registers 133 not selected in accordance with the address signals input and received synchronously with the command ACT.

The operation of the SDRAM 100 according to the third embodiment of the present invention will now be described with reference to the state transition diagram illustrated in FIG. 4.

The operation starts from an idle state 090 as a standby state where there are no memory cells 103 in the selected state.

In a state where the memory cells 103 are maintaining previously-written data, the data registers 133 are maintaining a reset state in accordance with an operation executed prior to the idle state 090.

Even in a case where the idle state 090 is obtained after the power is turned on, if a memory cell uses the amount of electricity accumulated in a floating body as data, it may be regarded that a state where the electric charge of the floating body is discharged is maintained.

The data registers 133 are maintaining the reset state in accordance with a power-on sequence compliant with the standard specifications of DDR-SDRAM (e.g., the standard specifications of DDR-SDRAM indicated in Non-Patent Literature 9 to Non-Patent Literature 23).

Therefore, in the idle state 090, the memory cell field indicates a maintained state, and the data register field indicates a maintained state.

The SDRAM 100 according to the third embodiment of the present invention remaining in the idle state 090 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command ACT is received, the SDRAM 100 according to the third embodiment of the present invention transitions from the idle state 090 to an activating state 091.

Address-related output signals of the address receiver 112 are transferred to the row decoder 118. One WL driver 134 is selected from the multiple WL drivers 134 and drives memory cells 103. The driven memory cells 103 are selected memory cells 103.

Data is read from the selected memory cells 103, is discriminated to "0" or "1" by the corresponding BL sense amplifiers 132, and is written into the corresponding data registers 133.

Therefore, in the activating state 091, the memory cell field indicates a read state, and the data register field indicates a written state.

When the data is read from the selected memory cells 103 and is completely stored in the data registers 133, the SDRAM 100 according to the third embodiment of the present invention transitions from the activating state 091 to an active state 092.

Alternatively, if a command is not input from a read-1 state 093, the SDRAM 100 according to the third embodiment of the present invention transitions to the active state 092 after a lapse of a predetermined time period compliant with the standard specifications of DDR-SDRAM (e.g., the standard specifications of DDR-SDRAM indicated in Non-Patent Literature 9 to Non-Patent Literature 23).

In either case, the SDRAM 100 transitions to the active state 092 upon completion of any operation.

Therefore, in the active state 092, the memory cell field indicates a maintained state, and the data register field indicates a maintained state.

The SDRAM 100 according to the third embodiment of the present invention remaining in the active state 092 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the third embodiment of the present invention transitions from the active state 092 to the read-1 state 093.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 093, the memory cell field indicates a maintained state, and the data register field indicates a read state and a maintained state.

The SDRAM 100 according to the third embodiment of the present invention remaining in the read-1 state 093 can receive the command RD again.

In this case, the SDRAM 100 according to the third embodiment of the present invention remains in the read-1 state 093.

If the SDRAM 100 according to the third embodiment of the present invention remaining in the read-1 state 093 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 092.

When remaining in the active state 092 or the read-1 state 093, the SDRAM 100 according to the third embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 transitions from the active state 092 or the read-1 state 093 to a read-2 state 094.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 094, the memory cell field indicates a maintained state, and the data register field indicates a read state and a maintained state.

The SDRAM 100 according to the third embodiment of the present invention remaining in the read-2 state 094 transitions to a pre-charge state 095 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 092 or an active state 097 or in the read-1 state 093 or a read-1 state 098, the SDRAM 100 according to the third embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the third embodiment of the present invention transitions from the active state 092 or 097 or the read-1 state 093 or 098 to a write-1 state 099.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-1 state 099, the memory cell field indicates a maintained state, and the data register field indicates a written state and a maintained state.

The SDRAM 100 according to the third embodiment of the present invention remaining in the write-1 state 099 can receive the command WR again.

In this case, the SDRAM 100 according to the third embodiment of the present invention remains in the write-1 state 099.

If the SDRAM 100 according to the third embodiment of the present invention remaining in the write-1 state 099 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 097.

If the SDRAM 100 according to the third embodiment of the present invention remaining in the read-1 state 098 or the write-1 state 099 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 097.

In either case, the SDRAM 100 transitions to the active state 097 upon completion of any operation.

In other words, in the active state 097, the memory cell field indicates a maintained state, and the data register field indicates a maintained state.

When remaining in the active state 097 or the write-1 state 099, the SDRAM 100 according to the third embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the third embodiment of the present invention transitions from the active state 097 or the write-1 state 099 to the read-1 state 098.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 098, the memory cell field indicates a maintained state, and the data register field indicates a read state and a maintained state.

The SDRAM 100 according to the third embodiment of the present invention remaining in the read-1 state 098 can receive the command RD again.

In this case, the SDRAM 100 according to the third embodiment of the present invention remains in the read-1 state 098.

If the SDRAM 100 according to the third embodiment of the present invention remaining in the read-1 state 098 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 097.

When remaining in the active state 097, the read-1 state 098, or the write-1 state 099, the SDRAM 100 according to the third embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 according to the third embodiment of the present invention transitions from the active state 097, the read-1 state 098, or the write-1 state 099 to a read-2 state 09B.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 09B, the memory cell field indicates a maintained state, and the data register field indicates a read state and a maintained state.

The SDRAM 100 according to the third embodiment of the present invention remaining in the read-2 state 09B transitions to a pre-charge state 096 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 097, the read-1 state 098, or the write-1 state 099, the SDRAM 100 according to the third embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the third embodiment of the present invention transitions from the active state 097, the read-1 state 098, or the write-1 state 099 to a write-2 state 09C.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-2 state 09C, the memory cell field indicates a maintained state, and the data register field indicates a written state and a maintained state.

The SDRAM 100 according to the third embodiment of the present invention remaining in the write-2 state 09C transitions to the pre-charge state 096 after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received.

Alternatively, when remaining in the read-2 state 09B, the SDRAM 100 according to the third embodiment of the present invention transitions to the pre-charge state 096 after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received.

As another alternative, when remaining in the active state 097, the read-1 state 098, or the write-1 state 099, the SDRAM 100 according to the third embodiment of the present invention transitions to the pre-charge state 096 after the command decoder 113 analyzes that the command PRE is received in accordance with input signals received by the command receiver 111 and input signals received by the address receiver 112.

The data registers 133 do not perform any operation and are maintaining data.

On the other hand, the selected memory cells 103 are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

In other words, in the pre-charge state 096, the memory cell field indicates an erased state, and the data register field indicates a maintained state.

Upon completion of the erase operation on the selected memory cells 103, the SDRAM 100 according to the third embodiment of the present invention transitions from the pre-charge state 096 to a pre-charge state 09A.

The SDRAM 100 according to the third embodiment of the present invention reads data from the data registers 133 and performs a write operation on the selected memory cells 103 in accordance with the data.

The write operation is performed only on the selected memory cell 103 where the data in the corresponding data register 133 is "1".

The write operation is executed by each WL driver 134 driving the WL and each BL/SL driver 135, where the data in the corresponding data register 133 is "1", driving the BL and SL to electric potentials suitable for the write operation.

During the write operation, each BL/SL driver 135 where the data in the corresponding data register 133 is "0" does not drive the BL and SL. Therefore, a write operation is not executed on the selected memory cell 103 where the data in the corresponding data register 133 is "0". In other words, the data in the selected memory cell 103 where the data in the corresponding data register 133 is "0" is maintained at "0".

Therefore, in the pre-charge state 09A, the memory cell field indicates a written state and a maintained state, and the data register field indicates a read state.

Upon completion of the write operation on the selected memory cells 103, the SDRAM 100 according to the third embodiment of the present invention transitions from the pre-charge state 09A to the pre-charge state 095.

Alternatively, when remaining in the read-2 state 094, the SDRAM 100 according to the third embodiment of the present invention transitions to the pre-charge state 095 after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received.

As another alternative, when remaining in the active state 092 or the read-1 state 093, the SDRAM 100 according to the third embodiment of the present invention transitions to the pre-charge state 095 after the command decoder 113 analyzes that the command PRE is received in accordance with input signals received by the command receiver 111 and input signals received by the address receiver 112.

The selected memory cells 103 are transitioned from the selected state to the deselected state. Even if the selected memory cells 103 are transitioned from the selected state to the deselected state, the data in the memory cells 103 is maintained.

The data registers 133 are reset.

Therefore, in the pre-charge state 095, the memory cell field indicates a maintained state, and the data register field indicates a reset state.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM 100 according to the third embodiment of the present invention transitions from the pre-charge state 095 to the idle state 090.

Unlike existing SDRAMs, when receiving the command WR or the command WRA, the SDRAM 100 according to the third embodiment of the present invention does not perform a write operation, at a data input timing from the input-output terminal DQ, on a memory cell 103 selected in accordance with address signals input and received synchronously with the command WR or the command WRA.

On the other hand, data obtained as a result of the data input receiver 114 discriminating a signal input via the input-output terminal DQ to "0" or "1" is written into a data register 133 selected in accordance with the address signals input and received synchronously with the command WR.

Before the selected memory cells 103 are transitioned from the selected state to the deselected state, the SDRAM 100 according to the third embodiment of the present invention performs a write operation on the selected memory cells 103 in accordance with the data in the data registers 133.

Data that is input to the SDRAM 100 up to this point and that needs to be written into the memory cells 103 in the selected state is written in all of the data registers 133.

Therefore, there is no write omission to the selected memory cells 103.

Moreover, data in the already-erased memory cells 103 remains as a copy in the data registers 133.

Therefore, by performing a write operation on the selected memory cells 103 in accordance with the data in the data registers 133, the data in the selected memory cells 103 can be recovered.

An existing SDRAM sometimes performs a write operation multiple times on the same memory cell. In contrast, the SDRAM 100 according to the third embodiment of the present invention performs each of a "0" data write operation and a "1" data write operation only once at most.

Similar to existing SDRAMs, when receiving the command RD, the SDRAM 100 according to the third embodiment of the present invention does not perform a read operation from the memory cells 103 selected in accordance with address signals input and received synchronously with the command RD.

A read operation from the data registers 133 having the copy of the data in the memory cells 103 selected in accordance with the command ACT is performed in advance, and the read data is output from the input-output terminal DQ by the data output driver 115.

Therefore, when the address signals input and received synchronously with the command RD after the command WR is received are the same as the address signals input and received synchronously with the command WR, even if a write operation is not performed on the memory cells 103, there is no problem in the read data since the data is written in the data registers 133.

Accordingly, even when the memory cells used have different optimal write voltages for data "0" and data "1" and require a data "0" write operation and a data "1" write operation at different timings, it is possible to comply with the standard specifications of DDR-SDRAM (e.g., the standard specifications of DDR-SDRAM indicated in Non-Patent Literature 9 to Non-Patent Literature 23) by performing the operation in accordance with the state transition diagram in FIG. 4.

The third embodiment of the present invention offers the following features.

### Features

The SDRAM according to the third embodiment of the present invention can comply with the standard specifications of DDR-SDRAM (e.g., the standard specifications of DDR-SDRAM indicated in Non-Patent Literature 9 to Non-Patent Literature 23) while using memory cells with different optimal write voltages for data "0" and data "1" to perform a data "0" write operation and a data "1" write operation at different timings.

### Fourth Embodiment

Similar to the SDRAM according to the second embodiment or the third embodiment of the present invention, an SDRAM according to a fourth embodiment of the present invention does not perform a "0" write operation and a "1" write operation at the same timing on memory cells.

When receiving either the command RD or the command RDA first in addition to the command WR or the command WRA from the external device of the SDRAM, the SDRAM according to the fourth embodiment of the present invention executes a write operation of a first logical value of binary data into memory cells selected in accordance with the command ACT from the external device of the SDRAM.

For the sake of convenience, a "0" data write operation to be executed may sometimes be indicated as "erase" hereinafter. There is no problem in the case of a "1" write operation.

If the SDRAM according to the fourth embodiment of the present invention receives the command RD or the command WR targeted toward the selected memory cells in a period from when the SDRAM receives the command ACT from the external device of the SDRAM to when the SDRAM receives the command PRE (the SDRAM may receive the command RD or the command WR any number of times between the command ACT and the command PRE), the SDRAM, after receiving the command PRE, writes a second logical value, different from the data written in an erase operation, of the binary data into the selected memory cells in accordance with the data in the data registers corresponding to the memory cells.

Alternatively, the SDRAM according to the fourth embodiment of the present invention writes the second logical value, different from the data written in the erase operation, of the binary data into the selected memory cells in accordance with the data in the data registers corresponding to the memory cells after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA or the command WRA is received with respect to the selected memory cells.

A time point after the lapse of the predetermined time period from the input of the command RDA corresponds to a time from when the command RD is input to when the command PRE becomes inputtable if the command RD is input in place of the command RDA, assuming that parameter values, such as the burst length, latency, and preamble, and the clock frequency are the same.

When viewed from the external device of the SDRAM, this time point is a timing at which the memory cells may be transitioned from the selected state to the deselected state.

A time point after the lapse of the predetermined time period from the input of the command WRA corresponds to a time from when the command WR is input to when the command PRE becomes inputtable if the command WR is input in place of the command WRA, assuming that parameter values, such as the burst length, latency, and preamble, and the clock frequency are the same.

When viewed from the external device of the SDRAM, this time point is a timing at which the memory cells may be transitioned from the selected state to the deselected state.

If writing of "0" as logical data is to be performed in the aforementioned erase operation, "1" data is written in accordance with the data in the corresponding data registers. If writing of "1" as logical data is to be performed in the aforementioned erase operation, "0" data is written in accordance with the data in the corresponding data registers.

Similar to the SDRAM according to the second embodiment or the third embodiment of the present invention, when the SDRAM according to the fourth embodiment receives the command WR or the command WRA, the SDRAM does not perform a write operation, at a data input timing from the external device of the SDRAM, on a memory cell selected in accordance with address signals input and received synchronously with the command WR or the command WRA.

However, even if the data is not written in the memory cell in response to the command WR, the data is written in the data register. After the command WR and onward, the data is read from the data register instead of the memory cell in response to the command RD, so that there is no problem in the read data.

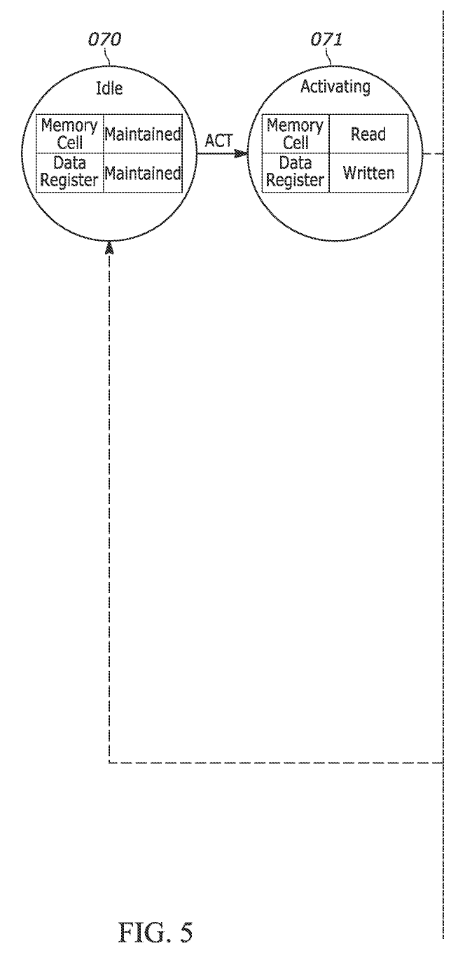

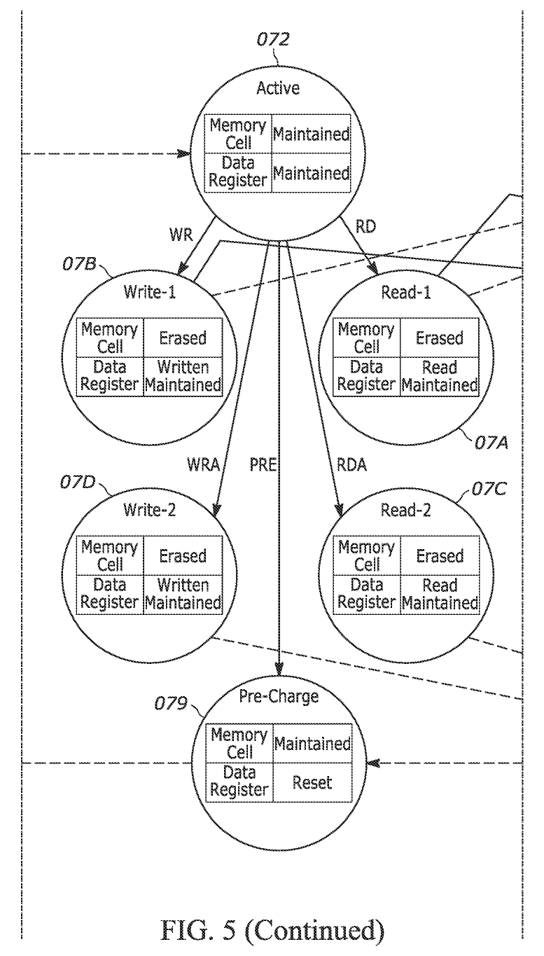

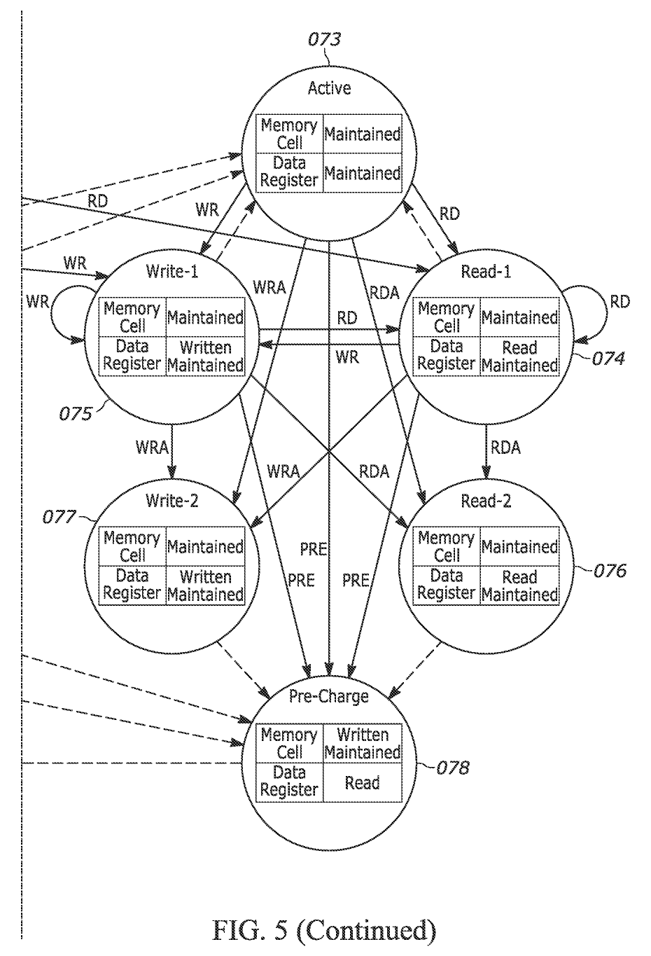

In order to describe the operation of the SDRAM according to the fourth embodiment of the present invention, the block diagram of the SDRAM in FIG. 1 and a state transition diagram illustrated in FIG. 5 will be used. Since the problems to be solved by the present invention and the gist of the present invention are not dependent on the number of banks, it is assumed that there is only one bank to simplify the description.

FIG. 5 is a state transition diagram of the memory cells 103 and the data registers 133 that operate by being selected in the SDRAM 100 according to the fourth embodiment of the present invention, and corresponds to the state transition diagram in FIG. 10.

Similar to FIG. 2, in each circle, the state of the SDRAM 100 as viewed from the external device of the SDRAM 100 is indicated, and corresponds to the state illustrated in FIG. 10. In addition, in each circle, the states of the memory cells 103 and the data registers 133 that operate by being selected in accordance with address signals input and received synchronously with the command ACT are indicated in a tabular form.

Similar to FIG. 10, each solid arrow indicates that the state transitions as a result of reception of a command accompanying the arrow, and each dashed arrow indicates that the state transitions regardless of a command.

Differences between FIGS. 5 and 10 are due to the following reasons.

The SDRAM 100 using memory cells that require that a "0" write operation and a "1" write operation be performed at different timings is to operate in compliance with the standard specifications indicated in Non-Patent Literature 9 to Non-Patent Literature 23 and created based on the assumption of using memory cells that enable a "0" write operation and a "1" write operation at the same timing.

Therefore, the state of the SDRAM 100 as viewed from the external device of the SDRAM 100 cannot be set identical to the state of the memory cells 103 and the state of the data registers 133, and does not need to be identical thereto.

Thus, if operations with respect to the memory cells 103 and the data registers 133 are performed in a single state of the SDRAM 100, the memory cells 103 and the data registers 133 may sometimes transition between different states.

Therefore, when a transition is made from a certain state to a different state in response to the same command, even if the state of the SDRAM 100 as viewed from the external device of the SDRAM 100 is the same, the memory cells 103 and the data registers 133 may sometimes be in different states due to operations previously performed on the memory cells 103 and the data registers 133.

Similar to the state transition diagram illustrated in FIG. 2, the state transition diagram illustrated in FIG. 5 is a state transition diagram of the memory cells 103 and the data registers 133 that are selected in accordance with address signals input and received synchronously with the command ACT.

Therefore, even when the SDRAM 100 according to the fourth embodiment of the present invention is in an activating state in response to the command ACT, a state transition does not occur in memory cells 103 and data registers 133 not selected in accordance with the address signals input and received synchronously with the command ACT.

The operation of the SDRAM 100 according to the fourth embodiment of the present invention will now be described with reference to the state transition diagram illustrated in FIG. 5.

The operation starts from an idle state 070 as a standby state where there are no memory cells 103 in the selected state.

In a state where the memory cells 103 are maintaining previously-written data, the data registers 133 are maintaining a reset state in accordance with an operation executed prior to the idle state 070.

Even in a case where the idle state 070 is obtained after the power is turned on, if a memory cell uses the amount of electricity accumulated in a floating body as data, it may be regarded that a state where the electric charge of the floating body is discharged is maintained.

The data registers 133 are maintaining the reset state in accordance with a power-on sequence compliant with the standard specifications of DDR-SDRAM (e.g., the standard specifications of DDR-SDRAM indicated in Non-Patent Literature 9 to Non-Patent Literature 23).

Therefore, in the idle state 070, the memory cell field indicates a maintained state, and the data register field indicates a maintained state.

The SDRAM 100 according to the fourth embodiment of the present invention remaining in the idle state 070 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command ACT is received, the SDRAM 100 according to the fourth embodiment of the present invention transitions from the idle state 070 to an activating state 071.

Address-related output signals of the address receiver 112 are transferred to the row decoder 118. One WL driver 134 is selected from the multiple WL drivers 134 and drives memory cells 103. The driven memory cells 103 are selected memory cells 103.

Data is read from the selected memory cells 103, is discriminated to "0" or "1" by the corresponding BL sense amplifiers 132, and is written into the corresponding data registers 133.

Therefore, in the activating state 071, the memory cell field indicates a read state, and the data register field indicates a written state.

When the data is read from the selected memory cells 103 and is completely stored in the data registers 133, the SDRAM 100 according to the fourth embodiment of the present invention transitions from the activating state 071 to an active state 072.

The memory cells 103 and the data registers 133 do not perform any operation and are maintaining data.

Therefore, in the active state 072, the memory cell field indicates a maintained state, and the data register field indicates a maintained state.

The SDRAM 100 according to the fourth embodiment of the present invention remaining in the active state 072 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the fourth embodiment of the present invention transitions from the active state 072 to a read-1 state 07A.

Address-related output signals of the address receiver 112 are transferred to the column decoder 117.

Output signals from data registers 133 selected by the column decoder 117 are output from the input-output terminal DQ by the data output driver 115 via the IO MUX 116.

Data registers 133 not selected by the column decoder 117 do not perform any operation and are maintaining data.

On the other hand, the selected memory cells 103 are entirely erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

Therefore, in the read-1 state 07A, the memory cell field indicates an erased state, and the data register field indicates a read state and a maintained state.

The SDRAM 100 according to the fourth embodiment of the present invention remaining in the read-1 state 07A can receive the command RD again.

In this case, upon completion of the erase operation on the selected memory cells 103, the SDRAM 100 according to the fourth embodiment of the present invention transitions to a read-1 state 074.

Upon completion of the erase operation on the selected memory cells 103, if the SDRAM 100 according to the fourth embodiment of the present invention remaining in the read-1 state 07A does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to an active state 073.

When remaining in the active state 072, the SDRAM 100 according to the fourth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the fourth embodiment of the present invention transitions from the active state 072 to a write-1 state 07B.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

Data registers 133 not selected by the column decoder 117 do not perform any operation and are maintaining data.

On the other hand, the selected memory cells 103 are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

Therefore, in the write-1 state 07B, the memory cell field indicates an erased state, and the data register field indicates a written state and a maintained state.

The SDRAM 100 according to the fourth embodiment of the present invention remaining in the write-1 state 07B can receive the command WR again.

In this case, upon completion of the erase operation on the selected memory cells 103, the SDRAM 100 according to the fourth embodiment of the present invention transitions to a write-1 state 075.

Upon completion of the erase operation on the selected memory cells 103, if the SDRAM 100 according to the fourth embodiment of the present invention remaining in the write-1 state 07B does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 073.

The SDRAM 100 according to the fourth embodiment of the present invention remaining in the active state 072 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 according to the fourth embodiment of the present invention transitions from the active state 072 to a read-2 state 07C.

Address-related output signals of the address receiver 112 are transferred to the column decoder 117.

Output signals from data registers 133 selected by the column decoder 117 are output from the input-output terminal DQ by the data output driver 115 via the IO MUX 116.

Data registers 133 not selected by the column decoder 117 do not perform any operation and are maintaining data.

On the other hand, the selected memory cells are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

Therefore, in the read-2 state 07C, the memory cell field indicates an erased state, and the data register field indicates a read state and a maintained state.

The SDRAM 100 according to the fourth embodiment of the present invention remaining in the read-2 state 07C transitions from the read-2 state 07C to a pre-charge state 078 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 072, the SDRAM 100 according to the fourth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the fourth embodiment of the present invention transitions from the active state 072 to a write-2 state 07D.

Address-related output signals of the address receiver 112 are transferred to the column decoder 117. Data obtained as a result of the data input receiver 114 discriminating signals input via the input-output terminal DQ to "0" or "1" is written via the IO MUX 116 into data registers 133 selected by the column decoder 117 from among multiple data registers 133.

Data registers 133 not selected by the column decoder 117 do not perform any operation and are maintaining data.

On the other hand, the selected memory cells are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

Therefore, in the write-2 state 07D, the memory cell field indicates an erased state, and the data register field indicates a written state and a maintained state.

The SDRAM 100 according to the fourth embodiment of the present invention remaining in the write-2 state 07D transitions from the write-2 state 07D to the pre-charge state 078 after a lapse of a predetermined time period compliant with the standard specifications of DDR-SDRAM (e.g., the standard specifications of DDR-SDRAM indicated in Non-Patent Literature 9 to Non-Patent Literature 23).

Upon completion of the erase operation on the selected memory cells 103, if the SDRAM 100 according to the fourth embodiment of the present invention remaining in the read-1 state 07A or the write-1 state 07B does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 073.

Alternatively, if the SDRAM 100 according to the fourth embodiment of the present invention remaining in the read-1 state 074 or the write-1 state 075 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 073.

In either case, the SDRAM 100 transitions to the active state 073 upon completion of any operation.

In other words, in the active state 073, the memory cell field indicates a maintained state, and the data register field indicates a maintained state.

When remaining in the active state 073 or the write-1 state 075, the SDRAM 100 according to the fourth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the fourth embodiment of the present invention transitions from the active state 073 or the write-1 state 075 to the read-1 state 074.

Alternatively, if the SDRAM 100 according to the fourth embodiment of the present invention remaining in the read-1 state 07A receives the command RD again, the SDRAM 100 transitions to the read-1 state 074 upon completion of an erase operation performed on the selected memory cells 103.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 074, the memory cell field indicates a maintained state, and the data register field indicates a read state and a maintained state.

The SDRAM 100 according to the fourth embodiment of the present invention remaining in the read-1 state 074 can receive the command RD again.

In this case, the SDRAM 100 according to the fourth embodiment of the present invention remains in the read-1 state 074.

If the SDRAM 100 according to the fourth embodiment of the present invention remaining in the read-1 state 074 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 073.

When remaining in the active state 073 or the read-1 state 074, the SDRAM 100 according to the fourth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the fourth embodiment of the present invention transitions from the active state 073 or the read-1 state 074 to the write-1 state 075.

Alternatively, if the SDRAM 100 according to the according to the fourth embodiment of the present invention remaining in the write-1 state 07B receives the command WR again, the SDRAM 100 transitions to the write-1 state 075 upon completion of an erase operation performed on the selected memory cells 103.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-1 state 075, the memory cell field indicates a maintained state, and the data register field indicates a written state and a maintained state.

The SDRAM 100 according to the fourth embodiment of the present invention remaining in the write-1 state 075 can receive the command WR again.

In this case, the SDRAM 100 according to the fourth embodiment of the present invention remains in the write-1 state 075.

If the SDRAM 100 according to the fourth embodiment of the present invention remaining in the write-1 state 075 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 073.

When remaining in the active state 073, the read-1 state 074, or the write-1 state 075, the SDRAM 100 according to the fourth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 according to the fourth embodiment of the present invention transitions from the active state 073, the write-1 state 075, or the write-1 state 075 to a read-2 state 076.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 076, the memory cell field indicates a maintained state, and the data register field indicates a read state and a maintained state.

The SDRAM 100 according to the fourth embodiment of the present invention remaining in the read-2 state 076 transitions to the pre-charge state 078 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 073, the read-1 state 074, or the write-1 state 075, the SDRAM 100 according to the fourth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the fourth embodiment of the present invention transitions from the active state 073, the read-1 state 074, or the write-1 state 075 to a write-2 state 077.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-2 state 077, the memory cell field indicates a maintained state, and the data register field indicates a written state and a maintained state.

The SDRAM 100 according to the fourth embodiment of the present invention transitions from the write-2 state 077 to the pre-charge state 078 after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received, the SDRAM 100 according to the fourth embodiment of the present invention transitions from the read-2 state 076 to the pre-charge state 078.

As another alternative, when remaining in the active state 073, the read-1 state 074, or the write-1 state 075, the SDRAM 100 according to the fourth embodiment of the present invention transitions to the pre-charge state 078 after the command decoder 113 analyzes that the command PRE is received in accordance with input signals received by the command receiver 111 and input signals received by the address receiver 112.

A write operation is performed on the selected memory cells 103 in accordance with data read from the data registers 133.

The write operation is performed only on the selected memory cell 103 where the data in the corresponding data register 133 is "1".

The write operation is executed by each WL driver 134 driving the WL and each BL/SL driver 135, where the data in the corresponding data register 133 is "1", driving the BL and SL to electric potentials suitable for the write operation.

During the write operation, each BL/SL driver 135 where the data in the corresponding data register 133 is "0" does not drive the BL and SL. Therefore, a write operation is not executed on the selected memory cell 103 where the data in the corresponding data register 133 is "0". In other words, the data in the selected memory cell 103 where the data in the corresponding data register 133 is "0" is maintained at "0".

Therefore, in the pre-charge state 078, the memory cell field indicates a written state and a maintained state, and the data register field indicates a read state.

Upon completion of the write operation on the selected memory cells 103, the SDRAM 100 according to the fourth embodiment of the present invention transitions from the pre-charge state 078 to a pre-charge state 079.

Alternatively, when remaining in the active state 072, the SDRAM 100 according to the fourth embodiment of the present invention transitions to the pre-charge state 079 after the command decoder 113 analyzes that the command PRE is received in accordance with input signals received by the command receiver 111 and input signals received by the address receiver 112.

The selected memory cells 103 are transitioned from the selected state to the deselected state. Even if the selected memory cells 103 are transitioned from the selected state to the deselected state, the data in the memory cells 103 is maintained.

The data registers 133 are reset.

Therefore, in the pre-charge state 079, the memory cell field indicates a maintained state, and the data register field indicates a reset state.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM 100 according to the fourth embodiment of the present invention transitions from the pre-charge state 079 to the idle state 070.

Unlike existing SDRAMs, when receiving the command WR or the command WRA, the SDRAM 100 according to the fourth embodiment of the present invention does not perform a write operation, at a data input timing from the input-output terminal DQ, on a memory cell 103 selected in accordance with address signals input and received synchronously with the command WR or the command WRA.

On the other hand, data obtained as a result of the data input receiver 114 discriminating a signal input via the input-output terminal DQ to "0" or "1" is written into a data register 133 selected in accordance with the address signals input and received synchronously with the command WR.

Before the selected memory cells 103 are transitioned from the selected state to the deselected state, the SDRAM 100 according to the fourth embodiment of the present invention performs a write operation on the selected memory cells 103 in accordance with the data in the data registers 133.

Data that is input to the SDRAM 100 up to this point and that needs to be written into the memory cells 103 in the selected state is written in all of the data registers 133.

Therefore, there is no write omission to the selected memory cells 103.

Moreover, data in the already-erased memory cells 103 remains as a copy in the data registers 133.

Therefore, by performing a write operation on the selected memory cells 103 in accordance with the data in the data registers 133, the data in the selected memory cells 103 can be recovered.

An existing SDRAM sometimes performs a write operation multiple times on the same memory cell. In contrast, the SDRAM 100 according to the fourth embodiment of the present invention performs each of a "0" data write operation and a "1" data write operation only once at most.

Similar to existing SDRAMs, when receiving the command RD, the SDRAM 100 according to the fourth embodiment of the present invention does not perform a read operation from the memory cells 103 selected in accordance with address signals input and received synchronously with the command RD.

A read operation from the data registers 133 having the copy of the data in the memory cells 103 selected in accordance with the command ACT is performed in advance, and the read data is output from the input-output terminal DQ by the data output driver 115.

Therefore, when the address signals input and received synchronously with the command RD after the command WR is received are the same as the address signals input and received synchronously with the command WR, even if a write operation is not performed on the memory cells 103, there is no problem in the read data since the data is written in the data registers 133.

Accordingly, even when the memory cells used have different optimal write voltages for data "0" and data "1" and require a data "0" write operation and a data "1" write operation at different timings, it is possible to comply with the standard specifications of DDR-SDRAM (e.g., the standard specifications of DDR-SDRAM indicated in Non-Patent Literature 9 to Non-Patent Literature 23) by performing the operation in accordance with the state transition diagram in FIG. 5.

The fourth embodiment of the present invention offers the following features.

### Features

The SDRAM according to the fourth embodiment of the present invention can comply with the standard specifications of DDR-SDRAM (e.g., the standard specifications of DDR-SDRAM indicated in Non-Patent Literature 9 to Non-Patent Literature 23) while using memory cells with different optimal write voltages for data "0" and data "1" to perform a data "0" write operation and a data "1" write operation at different timings.

### Fifth Embodiment

Similar to the SDRAM according to each of the second embodiment to the fourth embodiment of the present invention, an SDRAM according to a fifth embodiment of the present invention does not perform a "0" write operation and a "1" write operation at the same timing on memory cells.

The SDRAM according to the fifth embodiment of the present invention reads data from memory cells selected in accordance with address signals input and received synchronously with the command ACT from the external device of the SDRAM, stores the data into the corresponding data registers, and subsequently writes a first logical value of binary data into the selected memory cells.

For the sake of convenience, a "0" data write operation to be executed may sometimes be indicated as "erase" hereinafter. There is no problem in the case of a "1" write operation.

Therefore, after receiving the command ACT, the SDRAM according to the fifth embodiment copies the data from the selected memory cells to the data registers, and subsequently performs an erase operation on the selected memory cells. Unlike the SDRAM according to each of the second embodiment to the fourth embodiment of the present invention, the SDRAM according to the fifth embodiment performs the erase operation regardless of whether the command RD, the command RDA, the command WR, or the command WRA is input.

Furthermore, the SDRAM according to the fifth embodiment of the present invention is different from the SDRAM according to each of the second embodiment to the fourth embodiment of the present invention in that, regardless of whether the command RD, the command RDA, the command WR, or the command WRA is received after reception of the command ACT, the SDRAM according to the fifth embodiment of the present invention, after receiving the command PRE, writes a second logical value different from the data written in the erase operation into the memory cells in accordance with the data in the data registers corresponding to the memory cells.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received from the external device of the SDRAM, the SDRAM according to the fifth embodiment of the present invention writes the second logical value different from the data written in the erase operation into the memory cells in accordance with the data in the data registers corresponding to the selected memory cells.

A time point after the lapse of the predetermined time period from the input of the command RDA corresponds to a time from when the command RD is input to when the command PRE becomes inputtable if the command RD is input in place of the command RDA, assuming that parameter values, such as the burst length, latency, and preamble, and the clock frequency are the same.

When viewed from the external device of the SDRAM, this time point is a timing at which the memory cells may be transitioned from the selected state to the deselected state.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received from the external device of the SDRAM, the SDRAM according to the fifth embodiment of the present invention writes the second logical value different from the data written in the erase operation into the memory cells in accordance with the data in the data registers corresponding to the selected memory cells.

A time point after the lapse of the predetermined time period from the input of the command WRA corresponds to a time from when the command WR is input to when the command PRE becomes inputtable if the command WR is input in place of the command WRA, assuming that parameter values, such as the burst length, latency, and preamble, and the clock frequency are the same.

When viewed from the external device of the SDRAM, this time point is a timing at which the memory cells may be transitioned from the selected state to the deselected state.

Similar to the SDRAM according to each of the second embodiment to the fourth embodiment of the present invention, if writing of "0" as logical data is to be performed in the aforementioned erase operation, writing of data "1" as logical data is executed as a write operation in accordance with the data in the data registers.

If writing of "1" as logical data is to be performed in the aforementioned erase operation, writing of data "0" as logical data is executed as a write operation in accordance with the data in the data registers.

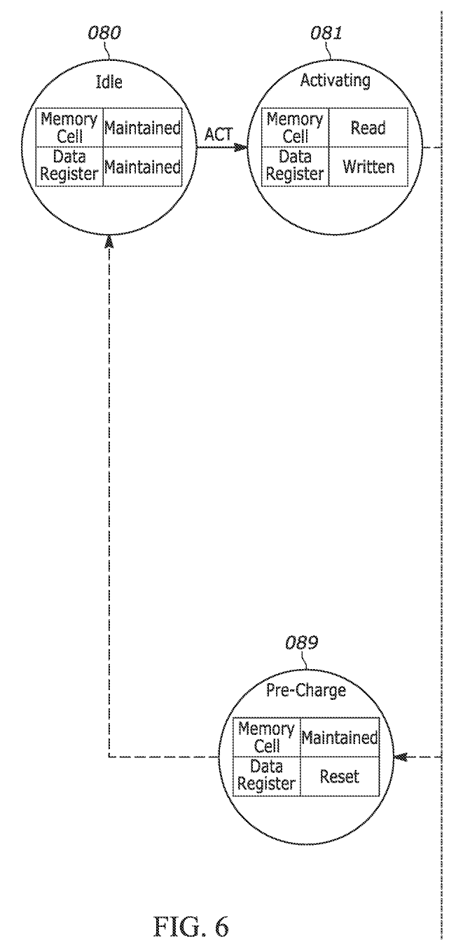

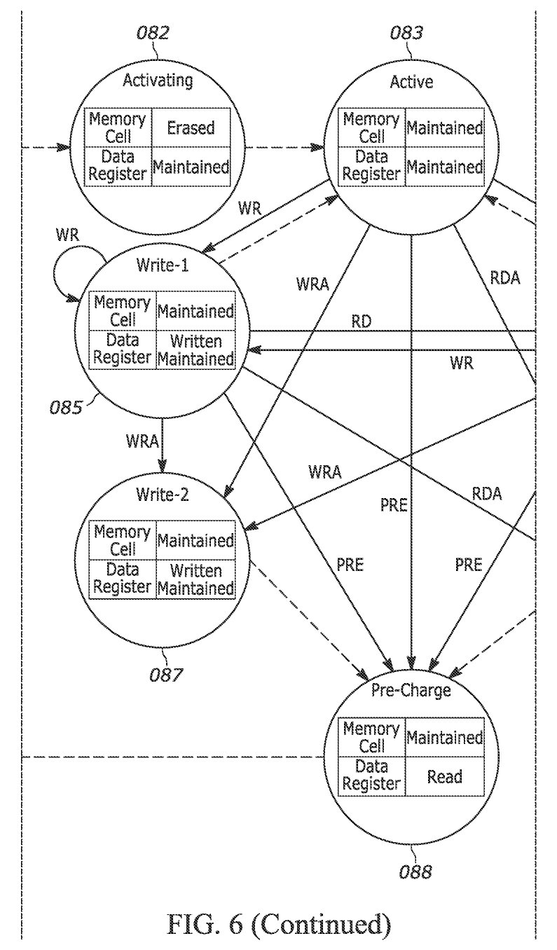

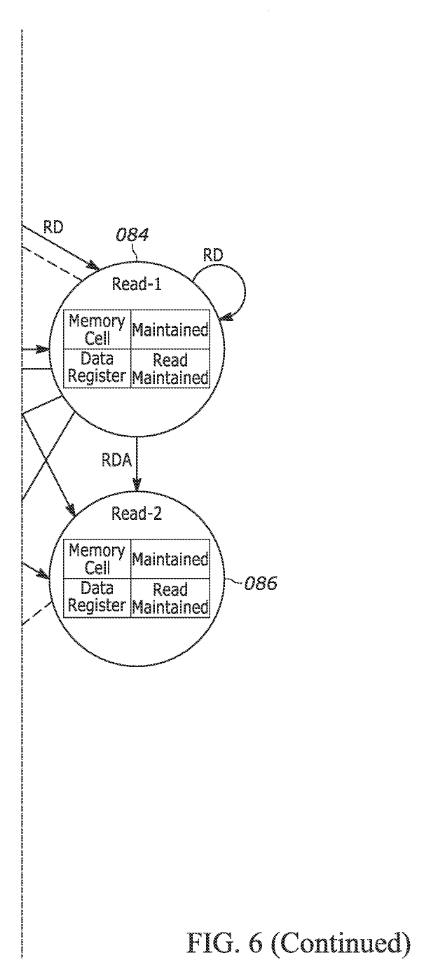

In order to describe the operation of the SDRAM according to the fifth embodiment of the present invention, the block diagram of the SDRAM in FIG. 1 and a state transition diagram illustrated in FIG. 6 will be used. Since the problems to be solved by the present invention and the gist of the present invention are not dependent on the number of banks, it is assumed that there is only one bank to simplify the description.

FIG. 6 is a state transition diagram of the memory cells 103 and the data registers 133 that operate by being selected in the SDRAM 100 according to the fifth embodiment of the present invention, and corresponds to the state transition diagram in FIG. 10.

Similar to FIG. 2, in each circle, the state of the SDRAM 100 as viewed from the external device of the SDRAM 100 is indicated, and corresponds to the state illustrated in FIG. 10. In addition, in each circle, the states of the memory cells 103 and the data registers 133 that operate by being selected in accordance with address signals input and received synchronously with the command ACT are indicated in a tabular form.

Similar to FIG. 10, each solid arrow indicates that the state transitions as a result of reception of a command accompanying the arrow, and each dashed arrow indicates that the state transitions regardless of a command.

Differences between FIGS. 6 and 10 are due to the following reasons.

The SDRAM 100 using memory cells that require that a "0" write operation and a "1" write operation be performed at different timings is to operate in compliance with the standard specifications indicated in Non-Patent Literature 9 to Non-Patent Literature 23 and created based on the assumption of using memory cells that enable a "0" write operation and a "1" write operation at the same timing.

Therefore, the state of the SDRAM 100 as viewed from the external device of the SDRAM 100 cannot be set identical to the state of the memory cells 103 and the state of the data registers 133, and does not need to be identical thereto.

Thus, if operations with respect to the memory cells 103 and the data registers 133 are performed in a single state of the SDRAM 100, the memory cells 103 and the data registers 133 may sometimes transition between different states.

Therefore, when a transition is made from a certain state to a different state in response to the same command, even if the state of the SDRAM 100 as viewed from the external device of the SDRAM 100 is the same, the memory cells 103 and the data registers 133 may sometimes be in different states due to operations previously performed on the memory cells 103 and the data registers 133.

Similar to the state transition diagram illustrated in FIG. 2, the state transition diagram illustrated in FIG. 6 is a state transition diagram of the memory cells 103 and the data registers 133 that are selected in accordance with address signals input and received synchronously with the command ACT.

Therefore, even when the SDRAM 100 according to the fifth embodiment of the present invention is in an activating state in response to the command ACT, a state transition does not occur in memory cells 103 and data registers 133 not selected in accordance with the address signals input and received synchronously with the command ACT.

The operation of the SDRAM 100 according to the fifth embodiment of the present invention will now be described with reference to the state transition diagram illustrated in FIG. 6.

The operation starts from an idle state 080 as a standby state where there are no memory cells 103 in the selected state.

In a state where the memory cells 103 are maintaining previously-written data, the data registers 133 are maintaining a reset state in accordance with an operation executed prior to the idle state 080.

Even in a case where the idle state 080 is obtained after the power is turned on, if a memory cell uses the amount of electricity accumulated in a floating body as data, it may be regarded that a state where the electric charge of the floating body is discharged is maintained.

The data registers 133 are maintaining the reset state in accordance with a power-on sequence compliant with the standard specifications of DDR-SDRAM (e.g., the standard specifications of DDR-SDRAM indicated in Non-Patent Literature 9 to Non-Patent Literature 23).

Therefore, in the idle state 080, the memory cell field indicates a maintained state, and the data register field indicates a maintained state.

The SDRAM 100 according to the fifth embodiment of the present invention remaining in the idle state 080 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command ACT is received, the SDRAM 100 according to the fifth embodiment of the present invention transitions from the idle state 080 to an activating state 081.

Address-related output signals of the address receiver 112 are transferred to the row decoder 118. One WL driver 134 is selected from the multiple WL drivers 134 and drives memory cells 103. The driven memory cells 103 are selected memory cells 103.

Data is read from the selected memory cells 103, is discriminated to "0" or "1" by the corresponding BL sense amplifiers 132, and is written into the corresponding data registers 133.

Therefore, in the activating state 081, the memory cell field indicates a read state, and the data register field indicates a written state.

When the data is read from the selected memory cells 103 and is completely stored in the data registers 133, the SDRAM 100 according to the fifth embodiment of the present invention transitions from the activating state 081 to an activating state 082.

The selected memory cells are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

On the other hand, the data registers 133 are maintaining data.

Therefore, in the activating state 082, the memory cell field indicates an erased state, and the data register field indicates a maintained state.

Upon completion of the erase operation on the selected memory cells 103, the SDRAM 100 according to the fifth embodiment of the present invention transitions from the activating state 082 to an active state 083.

In addition to the above, if the SDRAM 100 according to the fifth embodiment of the present invention remaining in a read-1 state 084 or a write-1 state 085 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 083.

In either case, the SDRAM 100 transitions to the active state 083 upon completion of any operation.

Therefore, in the active state 083, the memory cell field and the data register field both indicate a maintained state.

The SDRAM 100 according to the fifth embodiment of the present invention remaining in the active state 083 or the write-1 state 085 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the fifth embodiment of the present invention transitions from the active state 083 or the write-1 state 085 to the read-1 state 084.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 084, the memory cell field indicates a maintained state, and the data register field indicates a read state and a maintained state.

The SDRAM 100 according to the fifth embodiment of the present invention remaining in the read-1 state 084 can receive the command RD again.

In this case, the SDRAM 100 according to the fifth embodiment of the present invention remains in the read-1 state 084.

If the SDRAM 100 according to the fifth embodiment of the present invention remaining in the read-1 state 084 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 083.

When remaining in the active state 083 or the read-1 state 084, the SDRAM 100 according to the fifth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the fifth embodiment of the present invention transitions from the active state 083 or the read-1 state 084 to the write-1 state 085.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-1 state 085, the memory cell field indicates a maintained state, and the data register field indicates a written state and a maintained state.

The SDRAM 100 according to the fifth embodiment of the present invention remaining in the write-1 state 085 can receive the command WR again.

In this case, the SDRAM 100 according to the fifth embodiment of the present invention remains in the write-1 state 085.

If the SDRAM 100 according to the fifth embodiment of the present invention remaining in the write-1 state 085 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 083.

When remaining in the active state 083, the read-1 state 084, or the write-1 state 085, the SDRAM 100 according to the fifth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 according to the fifth embodiment of the present invention transitions from the active state 083, the read-1 state 084, or the write-1 state 085 to a read-2 state 086.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 086, the memory cell field indicates a maintained state, and the data register field indicates a read state and a maintained state.

The SDRAM 100 according to the fifth embodiment of the present invention remaining in the read-2 state 086 transitions to a pre-charge state 088 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 083, the read-1 state 084, or the write-1 state 085, the SDRAM 100 according to the fifth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the fifth embodiment of the present invention transitions from the active state 083, the read-1 state 084, or the write-1 state 085 to a write-2 state 087.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-2 state 087, the memory cell field indicates a maintained state, and the data register field indicates a written state and a maintained state.

After a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received, the SDRAM 100 according to the fifth embodiment of the present invention transitions from the write-2 state 087 to the pre-charge state 088.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received, the SDRAM 100 according to the fifth embodiment of the present invention transitions from the read-2 state 086 to the pre-charge state 088.

As another alternative, when remaining in the active state 083, the read-1 state 084, or the write-1 state 085, the SDRAM 100 according to the fifth embodiment of the present invention transitions to the pre-charge state 088 after the command decoder 113 analyzes that the command PRE is received in accordance with input signals received by the command receiver 111 and input signals received by the address receiver 112.

The SDRAM 100 according to the fifth embodiment of the present invention performs a write operation on the selected memory cells 103 in accordance with the data read from the data registers 133.

The write operation is performed only on the selected memory cell 103 where the data in the corresponding data register 133 is "1".

The write operation is executed by each WL driver 134 driving the WL and each BL/SL driver 135, where the data in the corresponding data register 133 is "1", driving the BL and SL to electric potentials suitable for the write operation.

During the write operation, each BL/SL driver 135 where the data in the corresponding data register 133 is "0" does not drive the BL and SL. Therefore, a write operation is not executed on the selected memory cell 103 where the data in the corresponding data register 133 is "0". In other words, the data in the selected memory cell 103 where the data in the corresponding data register 133 is "0" is maintained at "0".

Therefore, in the pre-charge state 088, the memory cell field indicates a written state and a maintained state, and the data register field indicates a read state.

Upon completion of the write operation on the selected memory cells 103, the SDRAM 100 according to the fifth embodiment of the present invention transitions from the pre-charge state 088 to a pre-charge state 089.

The selected memory cells 103 are transitioned from the selected state to the deselected state. Even if the selected memory cells 103 are transitioned from the selected state to the deselected state, the data in the memory cells 103 is maintained.

The data registers 133 are reset.

Therefore, in the pre-charge state 089, the memory cell field indicates a maintained state, and the data register field indicates a reset state.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM 100 according to the fifth embodiment of the present invention transitions from the pre-charge state 089 to the idle state 080.

Unlike existing SDRAMs, when receiving the command WR or the command WRA, the SDRAM 100 according to the fifth embodiment of the present invention does not perform a write operation, at a data input timing from the input-output terminal DQ, on a memory cell 103 selected in accordance with address signals input and received synchronously with the command WR or the command WRA.

On the other hand, data obtained as a result of the data input receiver 114 discriminating a signal input via the input-output terminal DQ to "0" or "1" is written into a data register 133 selected in accordance with the address signals input and received synchronously with the command WR.

Before the selected memory cells 103 are transitioned from the selected state to the deselected state, the SDRAM 100 according to the fifth embodiment of the present invention performs a write operation on the selected memory cells 103 in accordance with the data in the data registers 133.

Data that is input to the SDRAM 100 up to this point and that needs to be written into the memory cells 103 in the selected state is written in all of the data registers 133.

Therefore, there is no write omission to the selected memory cells 103.

Moreover, data in the already-erased memory cells 103 remains as a copy in the data registers 133.

Therefore, by performing a write operation on the selected memory cells 103 in accordance with the data in the data registers 133, the data in the selected memory cells 103 can be recovered.

An existing SDRAM sometimes performs a write operation multiple times on the same memory cell. In contrast, the SDRAM 100 according to the fifth embodiment of the present invention performs each of a "0" data write operation and a "1" data write operation only once at most.

Similar to existing SDRAMs, when receiving the command RD, the SDRAM 100 according to the fifth embodiment of the present invention does not perform a read operation from the memory cells 103 selected in accordance with address signals input and received synchronously with the command RD.

A read operation from the data registers 133 having the copy of the data in the memory cells 103 selected in accordance with the command ACT is performed in advance, and the read data is output from the input-output terminal DQ by the data output driver 115.

Therefore, when the address signals input and received synchronously with the command RD after the command WR is received are the same as the address signals input and received synchronously with the command WR, even if a write operation is not performed on the memory cells 103, there is no problem in the read data since the data is written in the data registers 133.

Accordingly, even when the memory cells used have different optimal write voltages for data "0" and data "1" and require a data "0" write operation and a data "1" write operation at different timings, it is possible to comply with the standard specifications of DDR-SDRAM (e.g., the standard specifications of DDR-SDRAM indicated in Non-Patent Literature 9 to Non-Patent Literature 23) by performing the operation in accordance with the state transition diagram in FIG. 6.

The fifth embodiment of the present invention offers the following features.

### Features

The SDRAM according to the fifth embodiment of the present invention can comply with the standard specifications of DDR-SDRAM (e.g., the standard specifications of DDR-SDRAM indicated in Non-Patent Literature 9 to Non-Patent Literature 23) while using memory cells with different optimal write voltages for data "0" and data "1" to perform a data "0" write operation and a data "1" write operation at different timings.

### Sixth Embodiment

Similar to the SDRAM according to each of the second embodiment to the fifth embodiment of the present invention, an SDRAM according to a sixth embodiment of the present invention does not perform a "0" write operation and a "1" write operation at the same timing on memory cells.

The SDRAM according to the sixth embodiment of the present invention reads data from memory cells selected in accordance with the command ACT from the external device of the SDRAM, and stores the data into the corresponding data registers.

After the command PRE is received from the external device of the SDRAM, a first logical value of binary data is written into the memory cells selected in accordance with the command ACT from the external device of the SDRAM.

For the sake of convenience, a "0" data write operation to be executed may sometimes be indicated as "erase" hereinafter.

Subsequently, a second logical value of the binary data is written into the memory cells in accordance with the data in the data registers corresponding to the memory cells. In this case, a "1" write operation is executed.

Alternatively, after a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received from the external device of the SDRAM, the SDRAM according to the sixth embodiment of the present invention writes the first logical value of the binary data into the memory cells selected in accordance with the command ACT from the external device of the SDRAM.

For the sake of convenience, a "0" data write operation to be executed may sometimes be indicated as "erase" hereinafter.

Subsequently, the second logical value of the binary data is written into the memory cells in accordance with the data in the data registers corresponding to the memory cells. In this case, a "1" write operation is executed.

As another alternative, after a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received from the external device of the SDRAM, the SDRAM according to the sixth embodiment of the present invention writes the first logical value of the binary data into the memory cells selected in accordance with the command ACT from the external device of the SDRAM.

For the sake of convenience, a "0" data write operation to be executed may sometimes be indicated as "erase" hereinafter.

Subsequently, the second logical value of the binary data is written into the memory cells in accordance with the data in the data registers corresponding to the memory cells. In this case, a "1" write operation is executed.

A time point after the lapse of the predetermined time period from the input of the command RDA corresponds to a time from when the command RD is input to when the command PRE becomes inputtable if the command RD is input in place of the command RDA, assuming that parameter values, such as the burst length, latency, and preamble, and the clock frequency are the same.

When viewed from the external device of the SDRAM, this time point is a timing at which the memory cells may be transitioned from the selected state to the deselected state.

A time point after the lapse of the predetermined time period from the input of the command WRA corresponds to a time from when the command WR is input to when the command PRE becomes inputtable if the command WR is input in place of the command WRA, assuming that parameter values, such as the burst length, latency, and preamble, and the clock frequency are the same.

When viewed from the external device of the SDRAM, this time point is a timing at which the memory cells may be transitioned from the selected state to the deselected state.

Similar to the SDRAM according to each of the second embodiment to the fifth embodiment of the present invention, if writing of "1" as logical data is to be performed in the aforementioned erase operation, writing of data "0" as logical data is to be executed after the erase operation.

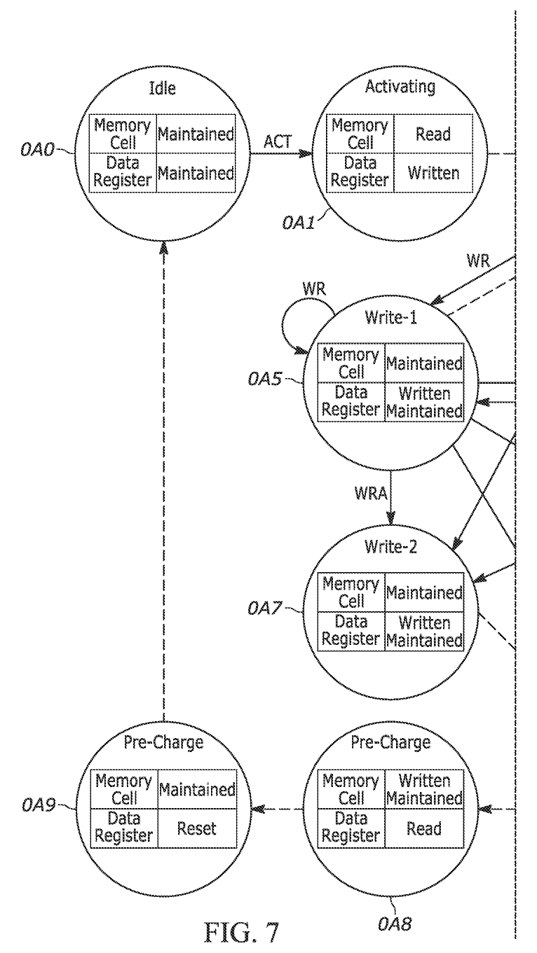

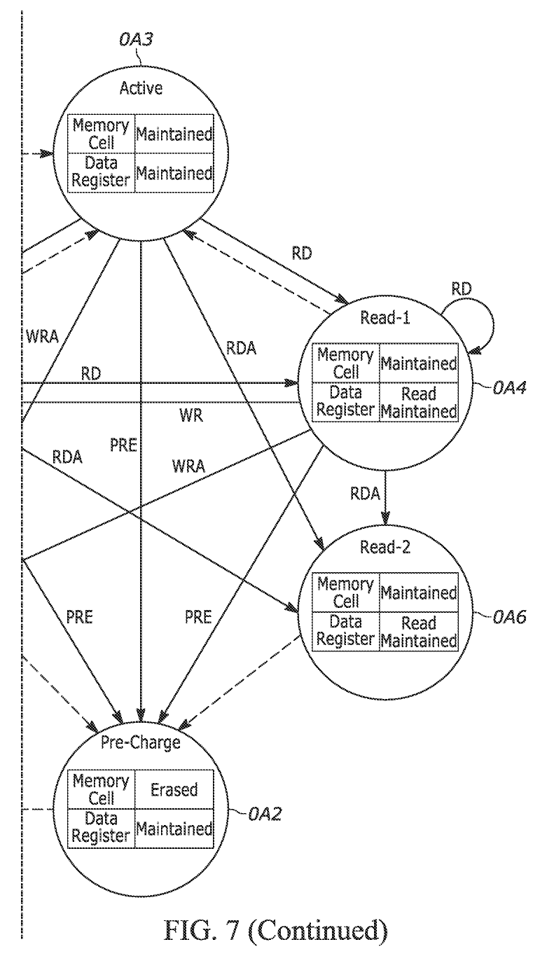

In order to describe the operation of the SDRAM according to the sixth embodiment of the present invention, the block diagram of the SDRAM in FIG. 1 and a state transition diagram illustrated in FIG. 7 will be used. Since the problems to be solved by the present invention and the gist of the present invention are not dependent on the number of banks, it is assumed that there is only one bank to simplify the description.

FIG. 7 is a state transition diagram of the memory cells 103 and the data registers 133 that operate by being selected in the SDRAM 100 according to the sixth embodiment of the present invention, and corresponds to the state transition diagram in FIG. 10.

Similar to FIG. 2, in each circle, the state of the SDRAM 100 as viewed from the external device of the SDRAM 100 is indicated, and corresponds to the state illustrated in FIG. 10. In addition, in each circle, the states of the memory cells 103 and the data registers 133 that operate by being selected in accordance with address signals input and received synchronously with the command ACT are indicated in a tabular form.

Similar to FIG. 10, each solid arrow indicates that the state transitions as a result of reception of a command accompanying the arrow, and each dashed arrow indicates that the state transitions regardless of a command.

Differences between FIGS. 7 and 10 are due to the following reasons.

The SDRAM 100 using memory cells that require that a "0" write operation and a "1" write operation be performed at different timings is to operate in compliance with the standard specifications indicated in Non-Patent Literature 9 to Non-Patent Literature 23 and created based on the assumption of using memory cells that enable a "0" write operation and a "1" write operation at the same timing.

Therefore, the state of the SDRAM 100 as viewed from the external device of the SDRAM 100 cannot be set identical to the state of the memory cells 103 and the state of the data registers 133, and does not need to be identical thereto.

Thus, if operations with respect to the memory cells 103 and the data registers 133 are performed in a single state of the SDRAM 100, the memory cells 103 and the data registers 133 may sometimes transition between different states.

Therefore, when a transition is made from a certain state to a different state in response to the same command, even if the state of the SDRAM 100 as viewed from the external device of the SDRAM 100 is the same, the memory cells 103 and the data registers 133 may sometimes be in different states due to operations previously performed on the memory cells 103 and the data registers 133.

Similar to the state transition diagram illustrated in FIG. 2, the state transition diagram illustrated in FIG. 7 is a state transition diagram of the memory cells 103 and the data registers 133 that are selected in accordance with address signals input and received synchronously with the command ACT.

Therefore, even when the SDRAM 100 according to the sixth embodiment of the present invention is in an activating state in response to the command ACT, a state transition does not occur in memory cells 103 and data registers 133 not selected in accordance with the address signals input and received synchronously with the command ACT.

The operation of the SDRAM 100 according to the sixth embodiment of the present invention will now be described with reference to the state transition diagram illustrated in FIG. 7.

The operation starts from an idle state 0A0 as a standby state where there are no memory cells 103 in the selected state.

In a state where the memory cells 103 are maintaining previously-written data, the data registers 133 are maintaining a reset state in accordance with an operation executed prior to the idle state 0A0.

Even in a case where the idle state 0A0 is obtained after the power is turned on, if a memory cell uses the amount of electricity accumulated in a floating body as data, it may be regarded that a state where the electric charge of the floating body is discharged is maintained.

The data registers 133 are maintaining the reset state in accordance with a power-on sequence compliant with the standard specifications of DDR-SDRAM (e.g., the standard specifications of DDR-SDRAM indicated in Non-Patent Literature 9 to Non-Patent Literature 23).

Therefore, in the idle state 0A0, the memory cell field indicates a maintained state, and the data register field indicates a maintained state.

The SDRAM 100 according to the sixth embodiment of the present invention remaining in the idle state 0A0 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command ACT is received, the SDRAM 100 according to the sixth embodiment of the present invention transitions from the idle state 0A0 to an activating state 0A1.

Address-related output signals of the address receiver 112 are transferred to the row decoder 118. One WL driver 134 is selected from the multiple WL drivers 134 and drives memory cells 103. The driven memory cells 103 are selected memory cells 103.

Data is read from the selected memory cells 103, is discriminated to "0" or "1" by the corresponding BL sense amplifiers 132, and is written into the corresponding data registers 133.

Therefore, in the activating state 0A1, the memory cell field indicates a read state, and the data register field indicates a written state.

When the data is read from the selected memory cells 103 and is completely stored in the data registers 133, the SDRAM 100 according to the sixth embodiment of the present invention transitions from the activating state 0A1 to an active state 0A3.

In addition to the above, if the SDRAM 100 according to the sixth embodiment of the present invention remaining in a read-1 state 0A4 or a write-1 state 0A5 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 0A3.

In either case, the SDRAM 100 transitions to the active state 0A3 upon completion of any operation.

Therefore, in the active state 0A3, the memory cell field and the data register field both indicate a maintained state.

The SDRAM 100 according to the sixth embodiment of the present invention remaining in the active state 0A3 or the write-1 state 0A5 can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RD is received, the SDRAM 100 according to the sixth embodiment of the present invention transitions from the active state 0A3 or the write-1 state 0A5 to the read-1 state 0A4.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-1 state 0A4, the memory cell field indicates a maintained state, and the data register field indicates a read state and a maintained state.

The SDRAM 100 according to the sixth embodiment of the present invention remaining in the read-1 state 0A4 can receive the command RD again.

In this case, the SDRAM 100 according to the sixth embodiment of the present invention remains in the read-1 state 0A4.

If the SDRAM 100 according to the sixth embodiment of the present invention remaining in the read-1 state 0A4 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 0A3.

When remaining in the active state 0A3 or the read-1 state 0A4, the SDRAM 100 according to the sixth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WR is received, the SDRAM 100 according to the sixth embodiment of the present invention transitions from the active state 0A3 or the read-1 state 0A4 to the write-1 state 0A5.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-1 state 0A5, the memory cell field indicates a maintained state, and the data register field indicates a written state and a maintained state.

The SDRAM 100 according to the sixth embodiment of the present invention remaining in the write-1 state 0A5 can receive the command WR again.

In this case, the SDRAM 100 according to the sixth embodiment of the present invention remains in the write-1 state 0A5.

If the SDRAM 100 according to the sixth embodiment of the present invention remaining in the write-1 state 0A5 does not receive any command during a predetermined time period compliant with the standard specifications of DDR-SDRAM (e.g., the standard specifications of DDR-SDRAM indicated in Non-Patent Literature 9 to Non-Patent Literature 23), the SDRAM 100 transitions to the active state 0A3.

When remaining in the active state 0A3, the read-1 state 0A4, or the write-1 state 0A5, the SDRAM 100 according to the sixth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command RDA is received, the SDRAM 100 according to the sixth embodiment of the present invention transitions from the active state 0A3, the read-1 state 0A4, or the write-1 state 0A5 to a read-2 state 0A6.

Address-related output signals of the address receiver 112 are transferred to the column decoder 117.

Output signals from data registers 133 selected by the column decoder 117 are output from the input-output terminal DQ by the data output driver 115 via the IO MUX 116.

On the other hand, selected memory cells 103 and data registers 133 not selected by the column decoder 117 do not perform any operation and are maintaining data.

In other words, in the read-2 state 0A6, the memory cell field indicates a maintained state, and the data register field indicates a read state and a maintained state.

The SDRAM 100 according to the sixth embodiment of the present invention remaining in the read-2 state 0A6 transitions to a pre-charge state 0A2 after a lapse of a predetermined time period compliant with the standard specifications of DDR-SDRAM (e.g., the standard specifications of DDR-SDRAM indicated in Non-Patent Literature 9 to Non-Patent Literature 23).

When remaining in the active state 0A3, the read-1 state 0A4, or the write-1 state 0A5, the SDRAM 100 according to the sixth embodiment of the present invention can cause the command receiver 111 to receive input signals via the input terminal COM, and can cause the address receiver 112 to receive input signals via the input terminal ADD.

Output signals of the command receiver 111 and command-related output signals of the address receiver 112 become input signals of the command decoder 113. When the command decoder 113 analyzes that the command WRA is received, the SDRAM 100 according to the sixth embodiment of the present invention transitions from the active state 0A3, the read-1 state 0A4, or the write-1 state 0A5 to a write-2 state 0A7.

Address-related output signals of the address receiver 112 are transferred to the column decoder 117.

Data obtained as a result of the data input receiver 114 discriminating signals input via the input-output terminal DQ to "0" or "1" is written via the IO MUX 116 into data registers 133 selected by the column decoder 117 from among multiple data registers 133.

On the other hand, selected memory cells 103 and data registers 133 not selected by the column decoder 117 do not perform any operation and are maintaining data.

In other words, in the write-2 state 0A7, the memory cell field indicates a maintained state, and the data register field indicates a written state and a maintained state.

After a lapse of a predetermined time period, compliant with the standard specifications of DDR-SDRAM (e.g., the standard specifications of DDR-SDRAM indicated in Non-Patent Literature 9 to Non-Patent Literature 23), from when the command WRA is received, the SDRAM 100 according to the sixth embodiment of the present invention transitions from the write-2 state 0A7 to the pre-charge state 0A2.

After a lapse of a predetermined time period, compliant with the standard specifications of DDR-SDRAM (e.g., the standard specifications of DDR-SDRAM indicated in Non-Patent Literature 9 to Non-Patent Literature 23), from when the command RDA is received, the SDRAM 100 according to the sixth embodiment of the present invention transitions from the read-2 state 0A6 to the pre-charge state 0A2.

When remaining in the active state 0A3, the read-1 state 0A4, or the write-1 state 0A5, the SDRAM 100 according to the sixth embodiment of the present invention transitions to the pre-charge state 0A2 after the command decoder 113 analyzes that the command PRE is received in accordance with input signals received by the command receiver 111 and input signals received by the address receiver 112.

The selected memory cells are erased. In other words, the selected memory cells 103 have "0" data written therein.

The erase operation is executed by each WL driver 134 driving the WL and each BL/SL driver 135 driving the BL and SL regardless of the data in the corresponding data register 133 to electric potentials suitable for the erase operation.

On the other hand, the data registers 133 are maintaining data.

Therefore, in the pre-charge state 0A2, the memory cell field indicates an erased state, and the data register field indicates a maintained state.

Upon completion of the erase operation on the selected memory cells 103, the SDRAM 100 according to the sixth embodiment of the present invention transitions from the pre-charge state 0A2 to a pre-charge state 0A8.

A write operation is performed on the selected memory cells 103 in accordance with data read from the data registers 133.

The write operation is performed only on the selected memory cell 103 where the data in the corresponding data register 133 is "1".

The write operation is executed by each WL driver 134 driving the WL and each BL/SL driver 135, where the data in the corresponding data register 133 is "1", driving the BL and SL to electric potentials suitable for the write operation.

During the write operation, each BL/SL driver 135 where the data in the corresponding data register 133 is "0" does not drive the BL and SL. Therefore, a write operation is not executed on the selected memory cell 103 where the data in the corresponding data register 133 is "0". In other words, the data in the selected memory cell 103 where the data in the corresponding data register 133 is "0" is maintained at "0".

Therefore, in the pre-charge state 0A8, the memory cell field indicates a written state and a maintained state, and the data register field indicates a read state.

Upon completion of the write operation on the selected memory cells 103, the SDRAM 100 according to the sixth embodiment of the present invention transitions from the pre-charge state 0A8 to a pre-charge state 0A9.

The selected memory cells 103 are transitioned from the selected state to the deselected state. Even if the selected memory cells 103 are transitioned from the selected state to the deselected state, the data in the memory cells 103 is maintained.

The data registers 133 are reset.

Therefore, in the pre-charge state 0A9, the memory cell field indicates a maintained state, and the data register field indicates a reset state.

After a lapse of a predetermined time period compliant with the standard specifications of DDR-SDRAM (e.g., the standard specifications of DDR-SDRAM indicated in Non-Patent Literature 9 to Non-Patent Literature 23), the SDRAM 100 according to the sixth embodiment of the present invention transitions from the pre-charge state 0A9 to the idle state 0A0.

Unlike existing SDRAMs, when receiving the command WR or the command WRA, the SDRAM 100 according to the sixth embodiment of the present invention does not perform a write operation, at a data input timing from the input-output terminal DQ, on a memory cell 103 selected in accordance with address signals input and received synchronously with the command WR or the command WRA.

On the other hand, data obtained as a result of the data input receiver 114 discriminating a signal input via the input-output terminal DQ to "0" or "1" is written into a data register 133 selected in accordance with the address signals input and received synchronously with the command WR.

Before the selected memory cells 103 are transitioned from the selected state to the deselected state, the SDRAM 100 according to the sixth embodiment of the present invention performs a write operation on the selected memory cells 103 in accordance with the data in the data registers 133.

Data that is input to the SDRAM 100 up to this point and that needs to be written into the memory cells 103 in the selected state is written in all of the data registers 133.

Therefore, there is no write omission to the selected memory cells 103.

Moreover, data in the already-erased memory cells 103 remains as a copy in the data registers 133.

Therefore, by performing a write operation on the selected memory cells 103 in accordance with the data in the data registers 133, the data in the selected memory cells 103 can be recovered.

An existing SDRAM sometimes performs a write operation multiple times on the same memory cell. In contrast, the SDRAM 100 according to the sixth embodiment of the present invention performs each of a "0" data write operation and a "1" data write operation only once at most.

Similar to existing SDRAMs, when receiving the command RD, the SDRAM 100 according to the sixth embodiment of the present invention does not perform a read operation from the memory cells 103 selected in accordance with address signals input and received synchronously with the command RD.

A read operation from the data registers 133 having the copy of the data in the memory cells 103 selected in accordance with the command ACT is performed in advance, and the read data is output from the input-output terminal DQ by the data output driver 115.

Therefore, when the address signals input and received synchronously with the command RD after the command WR is received are the same as the address signals input and received synchronously with the command WR, even if a write operation is not performed on the memory cells 103, there is no problem in the read data since the data is written in the data registers 133.

Accordingly, even when the memory cells used have different optimal write voltages for data "0" and data "1" and require a data "0" write operation and a data "1" write operation at different timings, it is possible to comply with the standard specifications of DDR-SDRAM (e.g., the standard specifications of DDR-SDRAM indicated in Non-Patent Literature 9 to Non-Patent Literature 23) by performing the operation in accordance with the state transition diagram in FIG. 7.

The sixth embodiment of the present invention offers the following features.

### Features

The SDRAM according to the sixth embodiment of the present invention can comply with the standard specifications of DDR-SDRAM (e.g., the standard specifications of DDR-SDRAM indicated in Non-Patent Literature 9 to Non-Patent Literature 23) while using memory cells with different optimal write voltages for data "0" and data "1" to perform a data "0" write operation and a data "1" write operation at different timings.

In the description of each of the second embodiment to the sixth embodiment of the present invention, the memory cells connected to the WL selected in accordance with the command ACT and the address signals input and received synchronously with the command ACT are all set to a selected state, and the BL sense amplifiers and data registers provided are equal in number to the memory cells. However, the configuration is not limited to the above so long as it accords with the gist of the present invention.

### Seventh Embodiment

A seventh embodiment of the present invention relates to wiring of a memory cell array for realizing the SDRAM according to each of the first embodiment to the sixth embodiment of the present invention.

In accordance with Patent Literature 3 to Patent Literature 8 and Non-Patent Literature 1 to Non-Patent Literature 7, a memory cell having "0" data written therein hardly allows any electric current to flow from the bit line to the source line during a read operation, whereas a memory cell having "1" data written therein allows electric current to flow from the bit line to the source line during a read operation.

The following is a conceivable case where, in the SDRAM according to each of the first embodiment to the sixth embodiment of the present invention, the source lines of the memory cell array are arranged parallel to the word lines, and "1" data is written in all of memory cells connected to one word line.

When a read operation is performed on all of the memory cells connected to the one word line in accordance with the command ACT, the electric current allowed to flow by the memory cells connected to the one word line flows through one common source line connected to the memory cells connected to the one word line.

The wiring resistance of the source line causes the electric potential of the source line to vary depending on the position of each memory cell, thus causing the read current to change and the read operation margin to decrease.

It is assumed that an erase operation, that is, a "0" data write operation, by the SDRAM according to each of the first embodiment to the sixth embodiment of the present invention is performed under "0" write conditions indicated in (b) in FIG. 1 or Table 1 in Non-Patent Literature 2.

As mentioned above, the electric current allowed to flow by the memory cells connected to the one word line flows through the one common source line connected to the memory cells connected to the one word line. According to Table 1 in Non-Patent Literature 2, the electric current that flows is greater than or equal to the electric current during a "1" data read operation. Due to the existence of a source line resistor, the source potential increases from 0 V, thus causing a "0" data write operation margin to decrease.

A "1" data write operation by the SDRAM according to each of the first embodiment to the sixth embodiment of the present invention may possibly be performed on all of the memory cells connected to the one word line. When "1" write conditions indicated in (a) in FIG. 1 or Table 1 in Non-Patent Literature 2 are used, Table 1 in Non-Patent Literature 2 indicates that the electric current that flows is greater than or equal to the electric current during a "1" data read operation. Due to the existence of the source line resistor, the source potential increases from 0 V, possibly leading to a decrease in a "1" data write operation margin.

The SDRAM according to the seventh embodiment of the present invention has the SL and the BL arranged parallel to each other, so as to avoid the aforementioned problems.

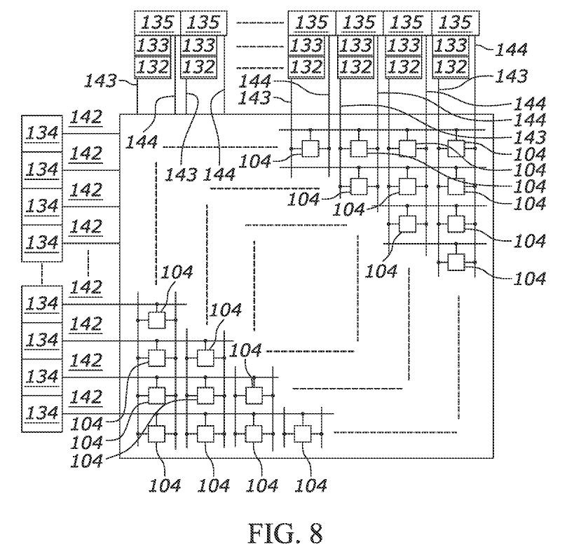

FIG. 8 illustrates the memory cell array 102 according to the seventh embodiment of the present invention and the connection relationships among memory cells 104, the local WL drivers 134, the BL/SL drivers 135, the BL sense amplifiers 132, and the data registers 133 within the memory cell array 102. SLs 144 are disposed orthogonally to WLs 142 and parallel to BLs 143.

Memory cells 104 connected to one WL 142 are equal in number to SLs 144. BLs 143 and SLs 144 are connected to the same number of BL/SL drivers 135. Each BL 143 is connected to the corresponding BL sense amplifier 132, the corresponding data register 133, and the corresponding BL/SL driver 135. Each SL 144 is connected to the corresponding BL/SL driver 135.

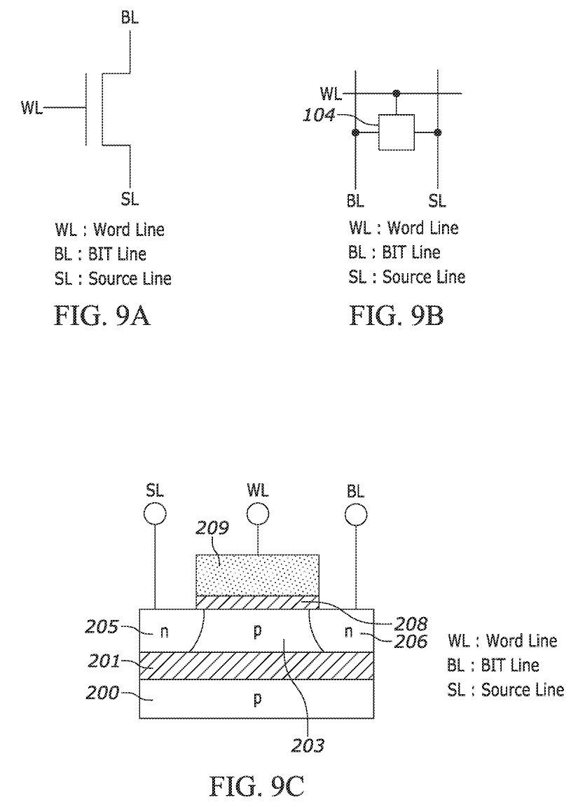

The reference sign of each memory cell 104 used in FIG. 8 is illustrated in FIG. 9B, and the memory cell 104 is constituted of a single NMOS field-effect transistor illustrated in FIG. 9A as a circuit diagram.

FIG. 9C is a cross-sectional view of the memory cell 104 constituted of a single NMOS field-effect transistor as an example. Each memory cell is constituted of a single NMOS field-effect transistor by arranging a data-storage floating body 203 isolated from a P-type substrate 200 by an insulating film 201, an N-type diffusion layer 205 that forms a source and that connects to an SL, an N-type diffusion layer 206 that forms a drain and that connects to a BL, and a gate conductive layer 209 also functioning as a WL on a gate insulating film 208 on the floating body 203.

As illustrated in FIG. 8, in the seventh embodiment of the present invention, the SLs and the BLs are disposed parallel to each other, so that an electric current flowing to each SL is the electric current allowed to flow by one memory cell and is the same as an electric current flowing to each BL. Therefore, a decrease in the operation margin depending on the position of the memory cell caused by the wiring resistance of the SL does not occur.

The seventh embodiment of the present invention offers the following features.

### Features

The SDRAM according to the seventh embodiment of the present invention has the SLs and the BLs disposed parallel to each other, so that an electric current flowing to each SL is the electric current allowed to flow by one memory cell and is the same as an electric current flowing to each BL. Therefore, even if the operation of the SDRAM according to any of the first embodiment to the sixth embodiment is performed, the SDRAM that can be provided does not cause a decrease in the operation margin depending on the position of the memory cell caused by wiring resistance.

### Other Embodiments

In addition to a silicon oxide film, a gate insulating film used in a transistor may be an insulating film other than a silicon oxide film, or may be a laminated film including a silicon oxide film and an insulating film other than a silicon oxide film. Therefore, each memory cell in the SDRAM according to the present invention and the gate insulating film of each transistor constituting a circuit are not limited to silicon oxide films alone, and may each use an insulating film other than a silicon oxide film, or may each use a laminated film including a silicon oxide film and an insulating film other than a silicon oxide film.

In the above embodiments, each memory cell that accumulates electric charge in a floating body and that distinguishes stored data based on the amount of electricity accumulated in the floating body is constituted of a single transistor having a floating body. Alternatively, the present invention is applicable to a clock-synchronous dynamic semiconductor memory device constituted of memory cells each provided with a selection transistor in addition to a storage element based on a single transistor having the floating body described in Non-Patent Literature 6.

The present invention is also applicable to a clock-synchronous dynamic semiconductor memory device that is described in Non-Patent Literature 7 and Patent Literature 8 and that is constituted of memory cells each including two series-connected transistors sharing a floating body serving as a storage node. The number of transistors that share the floating body serving as a storage node is not limited to two.

The present invention is also applicable to a clock-synchronous dynamic semiconductor memory device that is described in Patent Literature 6 and Patent Literature 7 and that is constituted of memory cells each including two gates that sandwich a floating body serving as a storage node therebetween.

The present invention is also applicable to a clock-synchronous dynamic semiconductor memory device constituted of memory cells each having the structure described in Patent Literature 9.

In addition to each memory cell that accumulates electric charge in a floating body and that distinguishes stored data based on the amount of electricity accumulated in the floating body, the present invention is also applicable to a case where a magnetic random access memory (MRAM), a phase change random access memory (PCRAM, a phase-change memory (PCM), or an ovonic unified memory (OUM)), or a resistive random access memory (ReRAM) is made compliant with the standard specifications of DDR-SDRAM (e.g., the standard specifications of DDR-SDRAM indicated in Non-Patent Literature 9 to Non-Patent Literature 23).

The present invention permits various embodiments and modifications so long as they do not depart from the spirit and scope of the present invention in a broad sense. Each of the above embodiments is a description of one embodiment of the present invention and is not intended to limit the scope of the present invention. The above embodiments and modifications may be arbitrarily combined. Moreover, each of the above embodiments having components partially removed therefrom, as necessary, is within the technical scope of the present invention.

The present invention can achieve a clock-synchronous dynamic semiconductor memory device (SDRAM) compliant with the standard specifications of a double-data-rate (DDR) clock-synchronous dynamic semiconductor memory device (SDRAM) (e.g., the standard specifications of DDR-SDRAM indicated in Non-Patent Literature 9 to Non-Patent Literature 23), which uses memory cells each constituted of a single existing transistor and a single capacitor, while ensuring an optimal operation for the memory cells by using memory cells that enable a dynamic semiconductor memory device (DRAM) with reduced manufacturing cost as a result of not having capacitors and that store data based on the amount of electricity accumulated in floating bodies.

What is claimed is:

1. An operation method of a clock-synchronous semiconductor memory device comprising a memory cell array including memory cells arranged in a matrix in two orthogonal directions in plan view on a semiconductor substrate, the clock-synchronous semiconductor memory device further comprising a data register that temporarily stores data and that is provided between the memory cell array and an input-output terminal of the clock-synchronous semiconductor memory device,
wherein the clock-synchronous semiconductor memory device has a command set serving as a group of commands for causing the clock-synchronous semiconductor memory device to operate,
wherein the command set at least comprises:
an active command for setting at least one memory cell of the memory cells to a selected state;
a pre-charge command for transitioning the at least one memory cell from the selected state to a deselected state;
a write command for setting the input-output terminal to an inputtable state for writing data;
a read command for setting the input-output terminal to an outputtable state for reading data;
a write command with auto-pre-charge for setting the input-output terminal to the inputtable state for writing data and for transitioning the at least one memory cell from the selected state to the deselected state regardless of the pre-charge command; and
a read command with auto-pre-charge for setting the input-output terminal to the outputtable state for reading data and for transitioning the at least one memory cell from the selected state to the deselected state regardless of the pre-charge command, and
wherein a write timing for the at least one memory cell set in the selected state is different from a write timing for writing data from the input-output terminal of the clock-synchronous semiconductor memory device into the data register.

2. The operation method of the clock-synchronous semiconductor memory device according to claim 1,
wherein the data from the input-output terminal of the clock-synchronous semiconductor memory device is written into the data register in response to the write command or the write command with auto-pre-charge.

3. The operation method of the clock-synchronous semiconductor memory device according to claim 2,
wherein data storable in each memory cell comprises two logical values as logical levels, and
wherein a write timing for writing data of a first logical value of the two logical values into the at least one memory cell set in the selected state is different from a write timing for writing data of a second logical value of the two logical values into the at least one memory cell set in the selected state.

4. The operation method of the clock-synchronous semiconductor memory device according to claim 3,
wherein the data storable in each memory cell comprises the two logical values as the logical values,
wherein a write operation of the data of the first logical value of the two logical values is performed on all of the memory cells that are selected in accordance with the active command, and
wherein a write operation of the data of the second logical value of the two logical values is performed only when the data stored in the data register corresponding to the at least one memory cell among all of the memory cells selected in accordance with the active command is the data of the second logical value of the two logical values.

5. The operation method of the clock-synchronous semiconductor memory device according to claim 4,
wherein the write operation of the data of the first logical value of the two logical values is performed on all of the memory cells selected in accordance with the active command after the data in all of the memory cells selected in accordance with the active command is written into the data register corresponding to all of the memory cells selected in accordance with the active command, and
wherein the write operation of the data of the second logical value of the two logical values is performed after the write operation of the data of the first logical value of the two logical values is performed on all of the memory cells selected in accordance with the active command.

6. The operation method of the clock-synchronous semiconductor memory device according to claim 5,
wherein even if the write command targeted toward the at least one memory cell selected in accordance with the active command is received multiple times before the at least one memory cell selected in accordance with the active command is transitioned from the selected state to the deselected state in accordance with the pre-charge command, the read command with auto-pre-charge, or the write command with auto-pre-charge, the write operation of each of the two logical values is performed once at most on the at least one memory cell selected in accordance with the active command.

7. The operation method of the clock-synchronous semiconductor memory device according to claim 5,
wherein the data of the first logical value of the two logical values is written into the at least one memory cell selected in accordance with the active command by using the data stored in the data register after:
the pre-charge command is received if the write command is received even once in a period from when the active command is received to when the pre-charge command is received;
the write command with auto-pre-charge is received; or
the read command with auto-pre-charge is received if the write command is received even once in a period from when the active command is received to when the read command with auto-pre-charge is received.

8. The operation method of the clock-synchronous semiconductor memory device according to claim 7,
wherein the data of the first logical value of the two logical values is written into the at least one memory cell selected in accordance with the active command by using the data stored in the data register after:
the pre-charge command is received if the write command is received even once in the period from when the active command is received to when the pre-charge command is received;
a time period corresponding to a time from when the write command is input to when the pre-charge command becomes inputtable elapses from when the write command with auto-pre-charge is received; or
a time period corresponding to a time from when the read command is input to when the pre-charge command becomes inputtable elapses from when the read command with auto-pre-charge is received if the write command is received even once in the period from when the active command is received to when the read command with auto-pre-charge is received.

9. The operation method of the clock-synchronous semiconductor memory device according to claim 5,
wherein the data of the first logical value of the two logical values is written into the at least one memory cell selected in accordance with the active command by using the data stored in the data register after:
the pre-charge command is received if the write command or the read command is received even once in a period from when the active command is received to when the pre-charge command is received;
the write command with auto-pre-charge is received; or
the read command with auto-pre-charge is received.

10. The operation method of the clock-synchronous semiconductor memory device according to claim 9,
wherein the data of the first logical value of the two logical values is written into the at least one memory cell selected in accordance with the active command by using the data stored in the data register after:
the pre-charge command is received if the write command or the read command is received even once in the period from when the active command is received to when the pre-charge command is received;
a time period corresponding to a time from when the write command is input to when the pre-charge command becomes inputtable elapses from when the write command with auto-pre-charge is received; or
a time period corresponding to a time from when the read command is input to when the pre-charge command becomes inputtable elapses from when the read command with auto-pre-charge is received.

11. The operation method of the clock-synchronous semiconductor memory device according to claim 5,
wherein the data of the first logical value of the two logical values is written into the at least one memory cell selected in accordance with the active command by using the data stored in the data register after:
the pre-charge command is received;
the write command with auto-pre-charge is received; or
the read command with auto-pre-charge is received.

12. The operation method of the clock-synchronous semiconductor memory device according to claim 11,
wherein the data of the first logical value of the two logical values is written into the at least one memory cell selected in accordance with the active command by using the data stored in the data register after:
the pre-charge command is received;
a time period corresponding to a time from when the write command is input to when the pre-charge command becomes inputtable elapses from when the write command with auto-pre-charge is received; or
a time period corresponding to a time from when the read command is input to when the pre-charge command becomes inputtable elapses from when the read command with auto-pre-charge is received.

13. The operation method of the clock-synchronous semiconductor memory device according to claim 7, the operation method comprising:
writing the data stored in the at least one memory cell selected in accordance with the active command into the data register corresponding to the at least one memory cell selected in accordance with the active command;
first receiving either the write command or the write command with auto-pre-charge; and
performing the write operation of the data of the first logical value of the two logical values on all of the memory cells selected in accordance with the active command.

14. The operation method of the clock-synchronous semiconductor memory device according to claim 9, the operation method comprising:
writing the data stored in the at least one memory cell selected in accordance with the active command into the data register corresponding to the at least one memory cell selected in accordance with the active command;
first receiving the write command, the write command with auto-pre-charge, the read command, or the read command with auto-pre-charge; and
performing the write operation of the data of the first logical value of the two logical values on all of the memory cells selected in accordance with the active command.

15. The operation method of the clock-synchronous semiconductor memory device according to claim 11, the operation method comprising:
writing the data stored in the at least one memory cell selected in accordance with the active command into the data register corresponding to the at least one memory cell selected in accordance with the active command; and
performing the write operation of the data of the first logical value of the two logical values on all of the memory cells selected in accordance with the active command.

16. The operation method of the clock-synchronous semiconductor memory device according to claim 5, the operation method comprising:
writing the data stored in the at least one memory cell selected in accordance with the active command into the data register corresponding to the at least one memory cell selected in accordance with the active command;
receiving the pre-charge command if receiving the write command even once before receiving the pre-charge command, or receiving the write command with auto-pre-charge, or receiving the read command with auto-pre-charge if receiving the write command even once before receiving the read command with auto-pre-charge;
performing the write operation of the data of the first logical value of the two logical values on all of the memory cells selected in accordance with the active command; and
performing the write operation of the data of the second logical value of the two logical values on the at least one memory cell selected in accordance with the active command by using the data stored in the data register.

17. The operation method of the clock-synchronous semiconductor memory device according to claim 5, the operation method comprising:
writing the data stored in the at least one memory cell selected in accordance with the active command into the data register corresponding to the at least one memory cell selected in accordance with the active command;
receiving the pre-charge command, the write command with auto-pre-charge, or the read command with auto-pre-charge;
performing the write operation of the data of the first logical value of the two logical values on all of the memory cells selected in accordance with the active command; and
performing the write operation of the data of the second logical value of the two logical values on the at least one memory cell selected in accordance with the active command by using the data stored in the data register.

18. The operation method of the clock-synchronous semiconductor memory device according to claim 5,
wherein the data register is disposed adjacent to the memory cell array, and the data register is equal in number to the at least one memory cell selected in accordance with the active command.

19. The operation method of the clock-synchronous semiconductor memory device according to claim 5,
wherein each memory cell has a first end connected to a bit line and a second end connected to a source line, and an extending direction of the bit line and an extending direction of the source line are parallel to each other.

20. The operation method of the clock-synchronous semiconductor memory device according to claim 5,
wherein each memory cell has a structure in which at least a portion of a floating body functioning as a storage node includes a metal-oxide-semiconductor field-effect transistor serving as an electric current path.
